(19) United States
(12) Patent Application Publication
(10) Pub. No.: US 2026/0352234 A1
(43) Pub. Date: Nov. 5, 2026

(54) METHODS, APPARATUS, AND SYSTEM FOR PARITY-CHECK POLAR CODING

(71) Applicant: Huawei Technologies Co., Ltd., Shenzhen (CN)

(72) Inventors: Huazi Zhang, Zhejiang (CN); Jianglei Ma, Ottawa (CA); Wen Tong, Ottawa (CA)

(21) Appl. No.: 19/705,349

(22) Filed: Jun. 11, 2026

Related U.S. Application Data
(63) Continuation of application No. PCT/CN2024/078045, filed on Feb. 22, 2024.
(60) Provisional application No. 63/608,940, filed on Dec. 12, 2023.

(51) Int. Cl. H03M 13/13

(52) U.S. Cl. CPC H03M 13/13

(57) ABSTRACT

Methods, apparatuses and systems for parity-check polar coding are described. In an example method, a parity-check encoded vector is generated based on a bit vector of information bits to be encoded. The parity-check encoded vector includes a plurality of subblocks, where information bits of a first subvector of the bit vector are assigned to information bit positions of a first subblock of the plurality of subblocks, and one or more parity-check bits generated from the information bits of the first subvector are assigned to frozen bit positions of the first subblock. A parity-check polar codeword is generated by applying a polar code to the parity-check encoded vector. The parity-check polar codeword is outputted.

### CROSS-REFERENCE TO RELATED APPLICATIONS

This application is a continuation of International Application No. PCT/CN2024/078045, filed on Feb. 22, 2024, which claims priority to U.S. provisional patent application No. 63/608,940, entitled “METHODS, APPARATUS, AND SYSTEM FOR PARITY-CHECK POLAR CODING”, filed Dec. 12, 2023. The disclosures of the aforementioned applications are hereby incorporated by reference in their entireties.

### TECHNICAL FIELD

The present disclosure relates to wireless communications, in particular methods, apparatuses and systems for parity-check (PC) polar coding.

### BACKGROUND

In wireless communications, channel quality is constantly changing due to the fading effects at both fast and slow scale. Accordingly, channel coding has always been designed to adapt to the channel states. Modulation coding scheme (MCS) adaptation is a powerful method to combat varying channel states, in which the modulation order and code length and coding rate can be changed in real time. Therefore, it requires that a channel coding scheme can flexibly change the code length and code rate in a fine-grained way, and at the same time achieve good error correction performance in all possible configurations. This fine-grained flexibility of channel codes is one of the most challenging problems for engineers in this domain.

At the same time, the complexity of both encoding and decoding algorithms need to be sufficiently low. In hardware, complexity can be evaluated through measuring chip area and energy efficiency. They are related to algorithmic complexity, but are more closely related to hardware cost and battery life. Therefore, there exists a desire to reduce implementation complexity when designing coding schemes.

Future communication systems, such as so-called sixth-generation (6G) systems, may aim to support several challenging scenarios, including for example immersive communication, massive communication, and hyper reliable and low-latency communication. The key performance indicators (KPIs) that are related to channel coding include coding gain, reliability, throughput, latency and their tradeoffs. For example, the throughput target of 6G may reach above 1 Tbps, and the energy efficiency target may decrease to 1 pJ/bit. Meanwhile, a coding scheme supporting flexible rate matching and incremental redundancy-hybrid automatic repeat request (IR-HARQ) schemes is also beneficial. Accordingly, it is desirable yet challenging to design a code ensemble to fulfill all these KPIs and capabilities.

### SUMMARY

In various examples, the present disclosure describes methods, systems and apparatuses for PC polar coding. In examples disclosed herein, PC encoding and polar encoding may be used to generate a PC polar codeword. IR-HARQ retransmission for polar codes may also be supported by examples disclosed herein.

Examples of the present disclosure include possible configurations for PC polar encoding according to physical channel types and/or code parameters and/or application scenarios. Examples of the present disclosure include possible configurations for PC polar coding, such as by allowing some or all frozen bit positions to carry PC bits. Examples of the present disclosure may provide technical advantages by enabling PC polar coding that has more stable performance in a wider range of code lengths and rates, compared to existing techniques for PC polar coding. Examples of the present disclosure may provide technical advantages in that PC polar coding can be supported for longer code lengths (e.g., greater than 20), with more stable performance (e.g., lower error rate).

Examples of the present disclosure include possible configurations for generating a polar codeword in which PC encoding is used on different subblocks of the codeword. By enabling PC polar coding in which PC encoding is performed on a subblock basis (rather than the entire codeword), savings in computing resources may be realized. For example, a decoder may only need to decode one subblock at a time instead of decoding the entire code length. This means that fewer memory resources and less chip area may be needed for the decoder. As well, a decoder may be able to successfully decode one subblock independently of any other subblock of the codeword. This means that it is possible for different subblocks to be transmitted separately. As such, examples of the present disclosure may provide technical advantages by supporting the use of PC polar coding in various retransmission schemes, including multiple transmissions and retransmissions (e.g., with multiple redundancy versions) being encoded as different subblocks in a codeword. The examples disclosed herein may also support IR-HARQ retransmission for both Low-density parity-check (LDPC) and polar codes.

Example methods in accordance with embodiments of the present disclosure may include rules or configurations to determine whether and how to perform PC encoding (e.g., whether to perform PC encoding according to physical channel types and/or code parameters and/or application scenarios); how to perform PC encoding (mark frozen bits as PC bits; etc.) and/or methods to perform PC encoding for different parts of the code (e.g., methods to perform subblock-wise PC encoding; PC encoding on different subblocks of the code; PC encoding on different redundancy versions and transmissions; etc.).

Some embodiments of the present disclosure may include one or more of the following features, which can be separately adopted, or work together as a complete solution.

An example first aspect of the present disclosure relates to methods to determine whether to perform PC encoding, including one or more of the following features: rules to specify whether to perform PC encoding according to physical channel types; rules to specify whether to perform PC encoding according to code parameters; rules to specify whether to perform PC encoding according to both physical channel types and code parameters; rules to specify whether to perform PC encoding according to application scenarios and priority; and/or rules to specify different ways to perform PC encoding and which way to select in different physical channels and coding parameters.

An example second aspect of the present disclosure relates to methods to perform PC encoding for different parts of the code. The methods may include one or more of the following configurations: apply PC-encoding to different subblocks of the code; and/or apply PC-encoding to different redundancy versions and transmissions.

Additional details of the disclosed examples and technical advantages thereof will be described further below.

In an example aspect, the present disclosure describes a method for generating a codeword, the method including: generating a parity-check encoded vector based on a bit vector of information bits to be encoded, the parity-check encoded vector comprising a plurality of subblocks, wherein information bits of a first subvector of the bit vector are assigned to information bit positions of a first subblock of the plurality of subblocks, and one or more parity-check bits generated from information bits of the first subvector are assigned to frozen bit positions of the first subblock; generating a parity-check polar codeword by applying a polar code to the parity-check encoded vector; and outputting the parity-check polar codeword.

In an example of the preceding example aspect, the one or more parity-check bits assigned to frozen bit positions of the first subblock may be generated independently of a second subblock of the plurality of subblocks.

In an example of the preceding example aspect, information bits of a second subvector of the bit vector may be assigned to information bit positions of the second subblock, and the second subblock maybe free of parity-check bits.

In an example of a preceding example aspect, the one or more parity-check bits generated from information bits of the first subvector may form a first set of one or more parity-check bits; information bits of a second subvector of the bit vector maybe assigned to information bit positions of the second subblock; and a second set of one or more parity-check bits generated from the information bits of the second subvector may be assigned to frozen bit positions of the second subblock, and the first set of one or more parity-check bits may be decoupled from the second set of one or more parity-check bits.

In an example of the preceding example aspect, a cyclic shift register may be used to generate the first set of one or more parity-check bits and to generate the second set of one or more parity-check bits, and the cyclic shift register may be cleared between generation of the first set of one or more parity-check bits and generation of the second set of one or more parity-check bits.

In an example of the preceding example aspect, the cyclic shift register may be cleared by resetting all bit values stored in the cyclic shift register to a single predefined value or to a set of predefined values.

In an example of the preceding example aspect, the set of predefined values may be based on a radio network temporary identifier (RNTI).

In an example of some of the preceding example aspects, a cyclic shift register may be used to generate the one or more parity-check bits from the information bits of the first subvector.

In an example of some the preceding example aspect, a pre-transformation matrix may be used to generate the one or more parity-check bits from the information bits of the first subvector.

In an example of the preceding example aspect, the pre-transformation matrix may be an upper triangular square matrix.

In an example of some of the preceding example aspects, a hash function may be used to generate the one or more parity-check bits from the information bits of the first subvector.

In an example of some of the preceding example aspects, a lookup table may be used to generate the one or more parity-check bits from the information bits of the first subvector.

In an example of any of the preceding example aspects, the first subvector may have a bit length that is a power of two.

In an example of any of the preceding example aspects, the bit vector of information bits may include a first polar codeword for a data transmission of having a first redundancy version and a second polar codeword for another data transmission having a second redundancy version, and the first subvector may correspond to the first polar codeword.

In an example of the preceding example aspect, the data transmission having the first redundancy version may be an initial data transmission, and the data transmission having the second redundancy version may be a data retransmission.

In an example of any of the preceding example aspects, all frozen bit positions of the first subblock having indices larger than an index of a first information bit in the first subblock may be assigned to carry parity-check bits.

In an example of any of the preceding example aspects, the parity-check polar codeword may be generated based on a type of physical channel that the parity-check polar codeword is to be transmitted over.

In an example of the preceding example aspect, the parity-check polar code may be generated based on: the type of physical channel being a physical uplink control channel that carries uplink control containing indicating feedback and scheduling request information; the type of physical channel being a physical uplink control channel that carries uplink control containing indicating channel state information; the type of physical channel being a physical uplink control channel that is not multiplexed on a physical uplink shared channel; the type of physical channel being any physical uplink control channel; the type of physical channel being a physical uplink control channel or a physical broadcast channel; the type of physical channel being a physical uplink control channel or a physical downlink control channel; the type of physical channel being a physical uplink control channel, a physical downlink control channel or a physical broadcast channel; the type of physical channel being a stage-1 physical downlink control channel; the type of physical channel being any physical control channel; or the type of physical channel being any physical uplink channel.

In an example of any of the preceding example aspects, the parity-check polar codeword may be generated based on one or more code parameters.

In an example of the preceding example aspect, the one or more code parameters may include one or more of: a code length within a maximum code length; an information block length within a maximum information block length; a code rate within a maximum code rate; or a code length within a maximum code length together with a code rate within a maximum code rate.

In an example of any of the preceding example aspects, the parity-check polar codeword may be generated based on one or more communication scenarios.

In an example of the preceding example aspect, the one or more communication scenarios may include one or more of: communications for ultra-reliable low-latency communications; or communications for high priority communications.

In an example of any of the preceding example aspects, the method may further include: transmitting the parity-check polar codeword over a communication channel.

In an example of any of the preceding example aspects, the method may further include: obtaining the bit vector of information bits.

In another example aspect, the present disclosure describes a method for decoding a codeword, the method including: decoding at least a first subblock of a parity-check polar codeword having a plurality of subblocks by using one or more parity-check bits in the first subblock to assist in decoding the first subblock; and outputting the decoded first subblock.

In an example of the preceding example aspect, the first subblock may be received in absence of a second subblock of the plurality of subblocks.

In an example of the preceding example aspect, a second subblock of the plurality of subblocks may be free of parity-check bits, the method further including: decoding the second subblock independently of the first subblock; and outputting the decoded second subblock.

In an example of the preceding example aspect, the method may further include: decoding a second subblock of the plurality of subblocks by using another one or more parity-check bits in the second subblock to assist in decoding the second subblock, independently of the first subblock; and outputting the decoded second subblock.

In an example of any of the preceding example aspects, the method may further include: receiving at least the first subblock.

In another example aspect, the present disclosure describes an apparatus including: a processor; and a memory including instructions that, when executed by the processor, cause the apparatus to perform any of the preceding example aspects of the method.

In another example aspect, the present disclosure describes an apparatus including: an encoding module configured to carry out the steps of any of the preceding example aspects of the method for generating a codeword; and a decoding module configured to carry out the receiving steps of any of the preceding example aspects of the method for decoding a codeword.

In another example aspect, the present disclosure describes a non-transitory computer readable medium having machine-executable instructions stored thereon, wherein the instructions, when executed by an apparatus, cause the apparatus to perform any of the preceding example aspects of the method.

In another example aspect, the present disclosure describes a processing module configured to control an apparatus to cause the apparatus to carry out any of the preceding example aspects of the method.

In another example aspect, the present disclosure describes a chip or a chipset comprising a processor configured to execute instructions to cause an apparatus to carry out any of the preceding example aspects of the method.

In another example aspect, the present disclosure describes a computer program characterized in that, when the computer program is run on a computer, the computer is caused to execute any of the preceding example aspects of the method.

### BRIEF DESCRIPTION OF THE DRAWINGS

Reference will now be made, by way of example, to the accompanying drawings which show example embodiments of the present application, and in which:

FIG. 1 is a simplified schematic illustration of a communication system, which may be used to implement examples of the present disclosure;

FIG. 2 is a block diagram illustrating an example of a communication system, which may be used to implement examples of the present disclosure;

FIG. 3 is a block diagram illustrating an example of devices of a communication system, which may be used to implement examples of the present disclosure;

FIG. 4 is a block diagram illustrating example units or modules in a device, which may be used to implement examples of the present disclosure;

FIG. 5 is a trellis graph illustrating an example of a polar code, which may be used to implement examples of the present disclosure;

FIG. 6 is a table illustrating an example interleaver scheme, which may be used to implement examples of the present disclosure;

FIG. 7 illustrates examples of puncturing or shortening using a circular buffer, which may be used to implement examples of the present disclosure;

FIG. 8 illustrates an example set of transmissions with incremental freezing, which may be implemented using examples of the present disclosure;

FIG. 9 illustrates an example implementation of a PC polar coding scheme using a cyclic shift register, which be implemented using examples of the present disclosure;

FIG. 10 illustrates an example of polar coding in an IR-HARQ scheme, which may be implemented using examples of the present disclosure;

FIG. 11 illustrates an example of polar transformation matrices that may be used for different transmissions in an IR-HARQ scheme, which may be used to implement examples of the present disclosure;

FIG. 12 illustrates an example of how information bits may be encoded to generate PC polar coded bits, in accordance with examples of the present disclosure;

FIG. 13A-13C illustrates examples of how PC encoding may be applied to different subblocks of a polar codeword, in accordance with examples of the present disclosure;

FIG. 14 illustrates an example of how PC encoding may be applied to arbitrary subblocks of a polar codeword, in accordance with examples of the present disclosure;

FIG. 15 illustrates an example of how two shorter polar codewords may be further combined and polarized into a longer polar codeword, in accordance with examples of the present disclosure;

FIG. 16 illustrates an example codeword in which different subblocks correspond to data transmissions with different redundancy versions, in accordance with examples of the present disclosure;

FIG. 17 illustrates another example codeword in which different subblocks correspond to data transmissions with different redundancy versions, in accordance with examples of the present disclosure;

FIG. 18 shows an example pseudocode for applying PC encoding to generate a vector to be encoded into a polar codeword, in accordance with examples of the present disclosure;

FIG. 19 shows an example pseudocode to generate a vector to be encoded into a polar codeword without PC encoding, in accordance with examples of the present disclosure;

FIGS. 20A-20B are block diagrams illustrating example units or modules in a device, which may be used to implement examples of the present disclosure;

FIG. 20C illustrates an example of an encoding chain, which may be used to implement examples of the present disclosure;

FIG. 21 is a flowchart illustrating an example method for generating a PC polar codeword, in accordance with examples of the present disclosure; and

FIG. 22 is a flowchart illustrating an example method for decoding a PC polar codeword, in accordance with examples of the present disclosure.

Similar reference numerals may have been used in different figures to denote similar components.

### DETAILED DESCRIPTION OF THE ILLUSTRATIVE EMBODIMENTS

In various examples, the present disclosure describes methods, apparatuses, and systems for PC polar coding. Examples of the present disclosure may enable methods of PC polar coding in which PC encoding is used with polar encoding in the encoding chain. Examples disclosed herein may support the use of PC polar coding in retransmission schemes (e.g., with multiple redundancy versions).

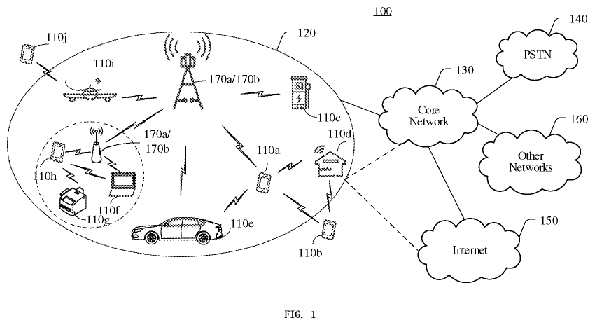

To assist in understanding the present disclosure, reference is first made to FIG. 1.

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

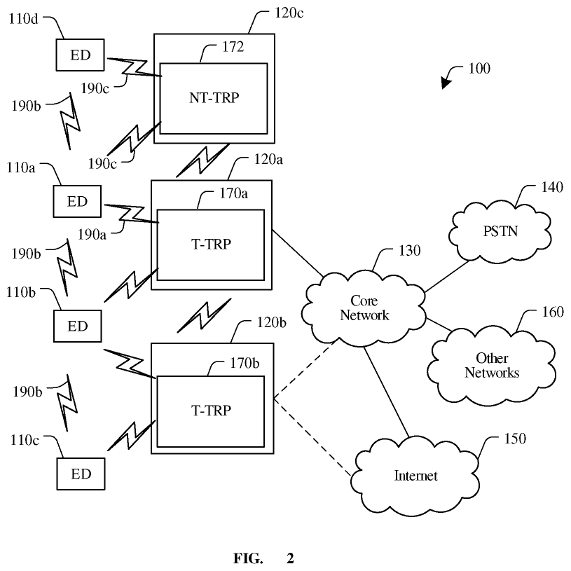

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a,170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

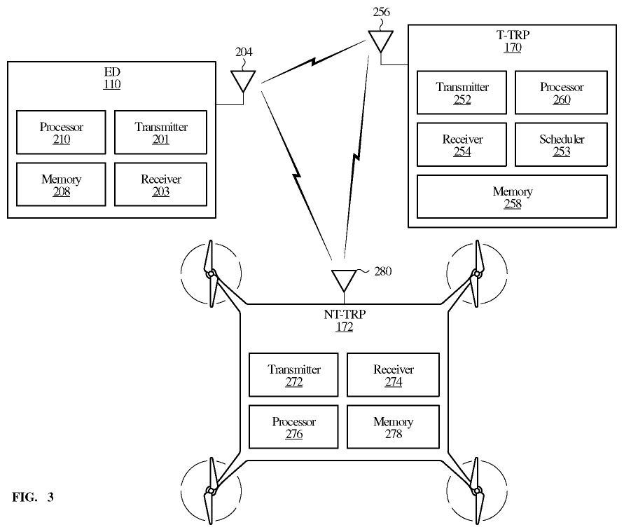

FIG. 3 illustrates another example of an ED 110 and a base station 170a, 170b and/or 170c. The ED 110 is used to connect persons, objects, machines, etc. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, etc.), an industrial device, or an apparatus in (e.g. communication module, modem, or chip) or comprising the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, etc.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g. beam angle information (BAI), received from the T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (e.g. in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g. a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g. through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (e.g. multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates an indication of beam direction, e.g. BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, e.g. a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (e.g., higher than physical layer) packet transmitted in a physical layer data channel, e.g. in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (e.g., “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, e.g. in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (e.g., a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (e.g. BAI) received from the T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, e.g. in the memory 278. Alternatively, some or all of the processor 276, the processing components of the transmitter 272, and the processing components of the receiver 274 may be implemented using dedicated circuitry, such as a programmed FPGA, a hardware accelerator (e.g., a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

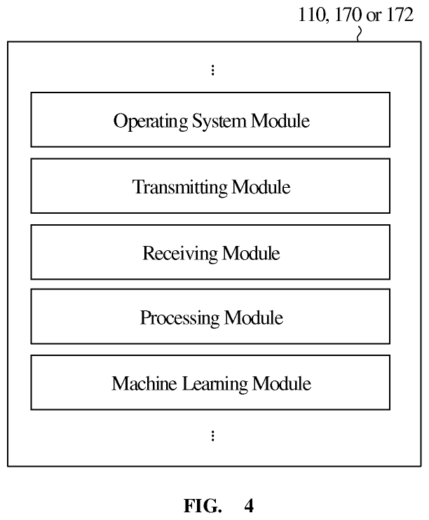

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit include a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

The channel coding module in communications systems encode K source bits into N code bits to provide error correction capability against adversary channel conditions such as noise and interference. The code rate is R=K/N. In practice, the code rate R is selected according to channel quality.

Polar codes are capacity-achieving codes and thus a great breakthrough in coding theory. As code length approaches infinity, the synthesized channels (also known as subchannels, which are created by or associated with the polar code) become either noiseless or pure noise. The noiseless subchannels are utilized to transport information, and their proportion is proven to achieve the channel capacity defined by Shannon. The above-mentioned channel polarization phenomenon occurs under successive cancellation (SC) or SC-based decoding, which has a relatively low complexity.

LDPC codes are capacity-approaching codes. LDPC codes may be defined by a PC matrix, which typically has far more zeros than ones—in other words, having low density. By properly designing the positions of the ones in the matrix, the decoding performance can be improved. Although LDPC codes can theoretically be viewed as a type of random code, certain structures, whether conceptual or physical, can facilitate the hardware implementation of LDPC encoders and decoders. A “Quasi-cyclic” (QC) structure is an example structure that may improve performance and/or implementation complexity. A QC-LDPC scheme first defines a smaller base matrix or base graph (BG), and then performs a “lifting” operation that replaces the ones in the base matrix or graph with a cyclic shifted version of an identity matrix.

Rate matching is performed after channel encoding, by either puncturing, shortening or repeating some code bits. The purpose of this operation is to obtain a code bit sequence of desired length for transmission over limited channel resources.

Rate-compatible polar coding is a desirable technology for wireless applications. In one example of polar code rate matching, a combination of puncturing, shortening and repetition is used together with a fixed reliability sequence to balance performance and complexity. In particular, subblock-wise interlacing and interleaving is used for both puncturing and shortening. The puncturing and shortening patterns are symmetric.

With mother code length N, and code length M, the specific rate matching scheme used is Repetition, when M>N; Puncturing, when K/M≤7/16; Shortening, when K/M>7/16.

Channel interleaving is applied after channel encoding and rate matching by permuting the code bits. The purpose is to provide stable or superior performance under high-order modulation or in a fading channel.

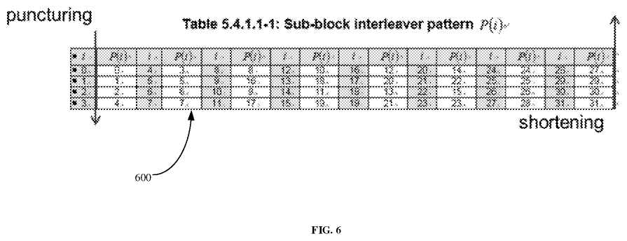

A subblock-wise interleaving is performed before puncturing and shortening. The interleaver partitions the length-N mother code into 32 subblocks of size N/32 and interlaces them. An example interleaver scheme is shown as table 600 in FIG. 6, reproduced from a 3GPP standard specification.

Hybrid automatic repeat request (HARQ) is a mechanism to provide reliable wireless transmission. It combines forward error correction (FEC) and automatic repeat request (ARQ). In HARQ, the initial transmission is a FEC code word with means (such as CRC bits) to support error detection at the receiver. If a decoding error is detected, the receiver will send back a negative acknowledgment (NACK) signaling to inform the transmitter of the error, and request a retransmission. The retransmitted bits can be directly selected from the initially transmitted bits, or incrementally generated code bits which form a longer code word with the initially transmitted bits. The former approach is called chase-combining HARQ (CC-HARQ) and the latter approach is called IR-HARQ. Typically, IR-HARQ outperforms CC-HARQ with the additional coding gain from incremental redundancy.

Polar codes belong to the class of linear block codes. For a polar code of length N, its generator matrix is G_{N}, and its encoding process is

$${x}_{1}^{N} = {u}_{1}^{N} {G}_{N} , where {u}_{1}^{N} = [ {u}_{1} , {u}_{2} , … , {u}_{N} ]$$

is the binary information vector,

$${x}_{1}^{N} = [ {x}_{1} , {x}_{2} , … , {x}_{N} ]$$

is the binary code vector. The N×N binary matrix

$${G}_{N} = {F}_{2}^{⊗ n} , where {F}_{2} = [ \begin{matrix}1 & 0 \\ 1 & 1\end{matrix} ]$$

is the polarization kernel matrix, n=log₂ N, and ⊗ is Kronecker product.

Typically, there are K information bits to be encoded into N code bits. Accordingly, the inequality K<N is given to obtain a code rate R=K/N<1. That implies only part of

$${u}_{1}^{N}$$

is used to carry information bits, and the rest are typically called frozen bits. Denote by I the information bit set (or information set), and F the frozen bit set (or frozen set), respectively. Sometimes, there is an additional PC bit set, denoted by P. The frozen bits are known (usually all zeros, but may also be other known values or sequences) before decoding, so they do not carry any payload information. The PC bits are PC bits generated from a subset of information bits. Therefore, the PC bits are known once the associated information bits are decoded. The decoding of polar codes attempts to recover all information bits.

The transmitted code length M may not always be the power of 2, i.e., M<N. In practice, puncturing and shortening are used to reduce transmitted code bits from N to M. For convenience, the present disclosure hereinafter refers to N as the mother code length, and M as the code length. In particular, punctured bits are non-transmitted bits unknown to the decoder, but shortened bits are non-transmitted bits known to the decoder (usually all zeros).

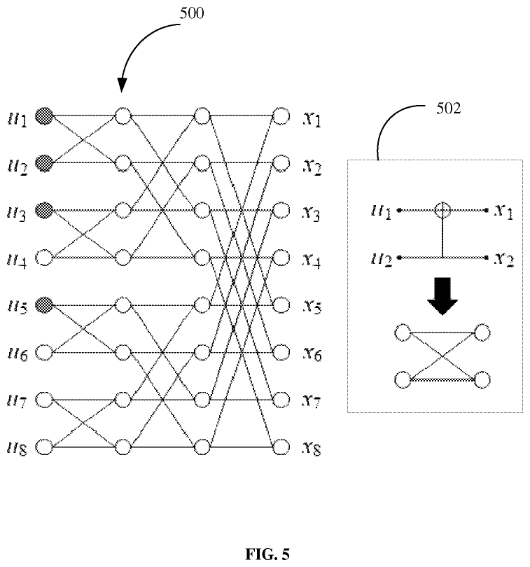

An example of a polar code with N=8, K=4 is shown in the trellis graph 500 of FIG. 5. Each “butterfly” 502 in the graph represents a polarization, i.e.,

$${x}_{1}^{2} = {u}_{1}^{2} [ \begin{matrix}1 & 0 \\ 1 & 1\end{matrix} ] .$$

In this example, the information set is I={u₄, u₆, u₇, u₈}, and the frozen set is F={u₁, u₂, u₃, u₅}.

Successive cancellation (SC) is the basic decoding algorithm for polar codes, where all the frozen bits and information bits are decoded sequentially, i.e., bit by bit. The preceding bits are typically always decoded first.

Successive cancellation list (SCL) is an enhanced decoding algorithm for polar codes, where multiple (e.g., a number L) SC decoding instances are executed. Each instance is called a “decoding path”. When decoding each binary bit, both “o” and “1” branches are extended to each path, creating 2L paths. Then, all 2L paths are compared, where the most likely L paths are kept, and the least likely L paths are discarded (or pruned). These path extension and pruning operations are performed during decoding of every information bit, until all information bits are decoded. At last, the most likely path is selected as the decoding output.

CRC-aided successive cancellation list (CA-SCL) works almost the same as SCL, except that in the last step, the most likely path that passes CRC check is selected as the decoding output.

Parity-check successive cancellation list (PC-SCL) works almost the same as SCL, except that when decoding PC bits, the parity check value of associated preceding bits is used as the bit decision result. PC bits may be considered a type of bit in addition to frozen bits and information bits.

Low Density Parity Check (LDPC) code is a channel coding scheme capable of achieving performance that approaches the Shannon limit, and furthermore features good overall performance and low complexity.

The LDPC code is encoded through a PC matrix. One class of LDPC code has a particular structure known as quasi-cyclic (QC). In a QC-LDPC code, a shifting value of each block is designed to avoid a bad structure such as a short circle, and improve a code distance. Decoding algorithms for LDPC codes include Min-Sum (MS) and Belief Propagation (BP). In terms of decoding performance, the BP decoding algorithm is better, but it has a large amount of information storage and a complex computation overhead, which is not convenient to hardware implementation. Therefore, Offset-MS and Normalized-MS decoding algorithms are used in realistic communication systems. An example LDPC code implementation extends the “1” in the basic graph (BG) by a square matrix, which is a cyclic shifted version of an identity matrix. The BG of QC-LDPC code can be defined by BG=(X, Y, F), where X corresponds to a variable, Y corresponds to a check equation, and F is its edge connections. The Tanner graph is obtained after QC lifting with an expansion factor Z_{c}. That is, a bipartite graph G=(V, C, E), where V is a variable node, C is a check node, E is a connected edge, and a corresponding parity matrix column quantity N=|V|=Z_{c}|X|. The quantity of rows of the check matrix M=|C|=Z_{c}|Y|, and a quantity of non-zero elements of the check matrix is |E|=Z|F|.

In an example, LDPC payloads include information block lengths ranging from 1 to 8448. The LDPC code implementation includes two PC matrices: BG1 and BG2. The same base graph, lifted by different lifting sizes, can adapt to a wide set of different code rates and lengths. This flexible implementation can be achieved, for example, by storing the Lifting Size and Shifting Value lists in the look-up tables, and then performing rate matching and IR-HARQ based on the tables.

In an example rate matching scheme for LDPC codes, a codeword before rate matching (referred as a mother codeword) includes three disjoint portions or parts, i.e., systematic bits, core parity check bits and extended parity check bits. Four different redundancy versions (RVs) including RV0, RV1, RV2 and RV3 are generated from the mother codeword after rate matching. In an initial transmission, RV0 is normally selected; in RV0, most of the systematic bits are included in the set of coded bits. Depending on the effective code rate, part of the core parity bits or all of the core parity check bits and extended parity bits are included in RV0. As a result, RV0 has the highest self-decodable ability among all RVs (i.e., RV0 can be self-decodable at highest code rate). In a retransmission, the transmitter may select RV1, RV2 or RV3. In this particular example, only RV3 is self-decodable, while RV1 and RV2 are not self-decodable at high code rate. At some code rates, RV1 and RV2 may only include parity check bits, resulting in unsuccessful decoding at the receiver.

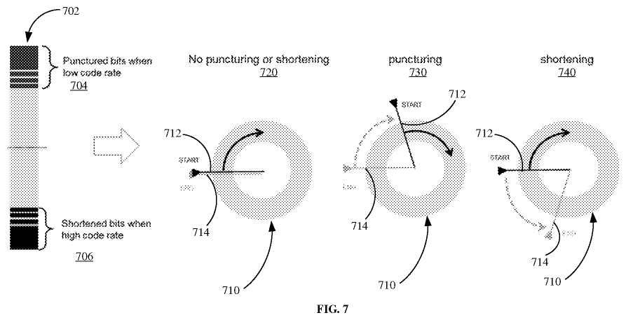

In some embodiments, since puncturing is performed from the 1^{st} code bit, and shortening is performed from the last code bit, the rate matching module is efficiently implemented through a cyclic buffer. All mother code bits are placed in the cyclic buffer, and puncturing is done by skipping the first few bits and selecting the remaining bits for transmission in clockwise order, and shortening is done by selecting bits for transmission in clockwise order and skipping the last few bits. An example cyclic buffer is illustrated in FIG. 7.

FIG. 7 illustrates an example of a mother code 702. As shown, if puncturing is performed (e.g., when the code rate is low), the punctured bits 704 start from the first code bit. If shortening is performed (e.g., when the code rate is high), the shortened bits 706 are the last few ending bits until the last code bit. FIG. 7 also illustrates an example of how a cyclic buffer 710 may be used for puncturing or shortening of the mother code 702. The bits of the mother code 702 are placed in the cyclic buffer 710, and the bits are selected from the cyclic buffer 710 starting at a starting position 712 and ending at an ending position 714. In an example 720 where no puncturing or shortening is performed, the starting position 712 is at the first code bit of the mother code 702 and the ending position 714 is at the last code bit of the mother code 702, such that all bits of the mother code 702 are selected. In an example 730 where puncturing is performed, the starting position 712 is shifted such that bit selection starts (N-M) bits after the first bit and the ending position 714 is at the last code bit of the mother code 702, such that (N-M) bits are punctured. In an example 740 where shortening is performed, the starting position 712 is at the first code bit of the mother code 702 and the ending position 714 is shifted such that bit selection stops (N-M) bits before the last bit, such that (N-M) bits are shortened.

Another polar code rate matching example involves an incremental freezing HARQ method, where transmissions of multiple short code words are supported. As more short codes are transmitted, the overall code length increases, and the overall code rate decreases.

In the first transmission, an (M₁, K) polar code is constructed, encoded and transmitted. The code rate is R₁=K/M₁. Usually, the code rate is determined such that R₁<C₁, where C₁ is the channel capacity of the first transmission. But in the case of faded channel or inaccurate channel estimation, there may be inequality R₁> C₁, and decoding will fail and a second transmission is required.

In the second transmission, K₂ least reliable information bits are selected from the K information bits in the first transmission. In practice, K₂ is chosen according to the estimated channel capacity of the second transmission. An (M₂, K₂) polar code is constructed accordingly and encoded and transmitted. However, if R₂>C₂, and decoding will fail again and a third transmission is required.

The third and fourth transmissions are constructed similarly, and so on.

At the receiver side (i.e., at the receiving apparatus), the decoder should always decode the last received code word, because it has the lowest code rate and thus the best chance of successful decoding. After the last transmission is correctly decoded, the corresponding information bits in all previous transmissions become known, and can be decoded as frozen bits with known values. This process is repeated as more code words are decoded, until all K bits in the first transmission is decoded. The term “incremental freezing” refers to the operations to additionally freeze some information bits in the previous transmissions once a later transmitted code word is decoded.

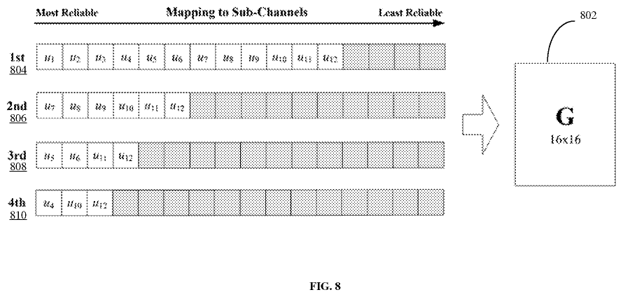

An example is illustrated in FIG. 8, where M₁=M₂=M₃=M₄=16, and K₁=12, K₂=6, K₃=4, K₄=2.

FIG. 8 illustrates an example set of sub-channels from most reliable sub-channel to least reliable sub-channel (it should be understood that the sub-channels are conceptually ordered from most reliable to least reliable, and the order illustrated in FIG. 8 may not indicate any actual ordering of the sub-channels). An example of four transmissions are shown. In this example, the code length is 16 for all four transmissions (i.e., M₁=M₂=M₃=M₄=16) meaning a 16×16 polar transformation matrix 802 (sometimes referred to as the generator matrix), indicated as G, is used for all four transmissions. The number of information bits to be transmitted is 12 (i.e., K=12).

In the first transmission 804, all 12 information bits (i.e., K₁=K=12) are selected, namely the bits {u₁, u₂, u₃, u₄, u₅, u₆, u₇, u₈, u₉, u₁₀, u₁₁, u₁₂,}. An (M₁, K₁) polar code is constructed, encoded and transmitted over the most reliable sub-channels. In the case of faded channel or inaccurate channel estimation, the code rate may exceed the channel capacity and decoding may fail. A second transmission is required.

In the second transmission 806, the K₂-th least reliable information bits are selected from the information bits sent in the first transmission 804. In this example, K₂=6 meaning that the information bits sent in the 6 least reliable sub-channels, namely the bits {u₇, u₈, u₉, u₁₀, u₁₁, u₁₂,}, are selected. An (M₂, K₂) polar code is constructed accordingly and encoded and transmitted over the most reliable sub-channels. If decoding fails again, a third transmission is required.

In the third transmission 808, the selected bits are selected from the least reliable information bits sent in the second transmission 806 as well as the least reliable bits of the first transmission 804 that have not been retransmitted. Specifically, of the K₃=4 information bits selected for the third transmission 808, the two least reliable information bits of the second transmission 806 are selected (namely {u₁₁, u₁₂}) and the two least reliable information bits of the first transmission 804 that have not been retransmitted are selected (namely {u₅, u₆}). An (M₃, K₃) polar code is constructed accordingly and encoded and transmitted over the most reliable sub-channels. If decoding fails again, a fourth transmission is required.

In the fourth transmission 810, the selected bits are selected from the least reliable of the not yet retransmitted information bits of all preceding transmissions. Specifically, of the K₄=3 information bits selected for the fourth transmission 810, the one least reliable information bit of the third transmission 808 is selected (namely {u₁₂}), the one least reliable of the not yet retransmitted information bits of the second transmission 806 is selected (namely {u₁₀}), and the one least reliable of the not yet retransmitted information bits of the second transmission 806 is selected (namely {u₄}). An (M₄, K₄) polar code is constructed accordingly and encoded and transmitted over the most reliable sub-channels.

In this example, decoding is successful after the fourth transmission 810. Then, using the successfully decoded information bits of the fourth transmission 810, the remaining information bits of the third transmission 808 can be decoded. The information bits of the second transmission 806 can then be decoded after successful decoding of the information bits of the third transmission 808, and so forth until all 12 information bits are successfully decoded.

PC polar codes may be used to improve minimum distance of polar codes. PC polar codes may also be used to support IR-HARQ. In the latter case, the PC bits are used to couple multiple retransmissions into a longer polar code with extra coding gain.

The PC bits may be considered an additional type of bits in addition to information and frozen bits. The values of the PC bits are determined by their preceding information bits, and specifically, by binary linear combinations of a subset of preceding information bits. The binary linear combination is specified by a PC function:

uᵢ+uⱼ+ . . . +uₖ=0,
where i<j< . . . <k are bit indices. Since k is the largest index in this PC function, uₖ may be referred to as a PC bit, whose value is the binary sum of all other (preceding) bits in the PC function.

In order to improve the minimum distance (or weight spectrum), the PC bit positions are selected from the indices among the non-frozen bit set with minimum row weights in the polar transformation matrix G_{N}. The non-frozen bit set is the complement set of the frozen set.

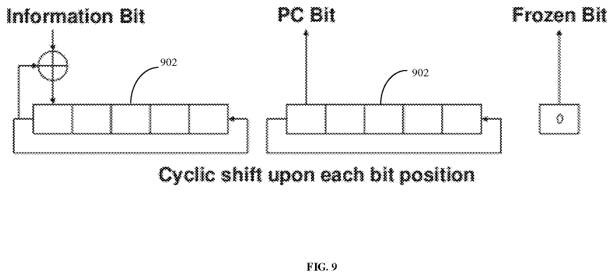

An example polar code scheme uses a simple and hardware-friendly PC function over fixed p-sized spacing. For example, p can be set to a value of 5. That is, for a PC bit with index k, its value is the sum modulo 2 of all preceding information bits with spacing 5. That is, uₖ=uₖ₋₅+uₖ₋₁₀+uₖ₋₁₅+ . . . . The PC bits may be easily generated by a p-length cyclic shift register, as shown in FIG. 9.

FIG. 9 illustrates an example of how a cyclic shift register may be used during assignment of bits to bit positions (where different bit positions correspond to different sub-channels). In this example, p has a value of 5 (i.e., a cyclic shift register that holds 5 bit values is used). For a bit position at a current index, it is determined whether that bit position should carry an information bit, a PC bit or a frozen bit. If the bit position is to carry an information bit, the bit value of the information bit is stored in a cyclic shift register 902 and the cyclic shift register 902 is shifted by one. If the bit position is to carry a PC bit, the bit value of the PC bit is outputted from the cyclic shift register 902 and the cyclic shift register 902 is shifted by one. Frozen bits in this example always have a value of 0 and the cyclic shift register 902 is shifted by one.

Some example of PC polar codes may also be implemented to support IR-HARQ. In such examples, the PC bits may no longer primarily serve a purpose for improving minimum code distance, but rather the PC bits may primarily be for coupling multiple retransmissions into a longer polar code with extra coding gain.

The PC functions used for IR-HARQ may be considered a special case, where some information bits are copied from the initial transmitted code block to a retransmitted code block. This one-to-one parity checking between the two shorter code blocks effectively couples the two code blocks into a longer code block.

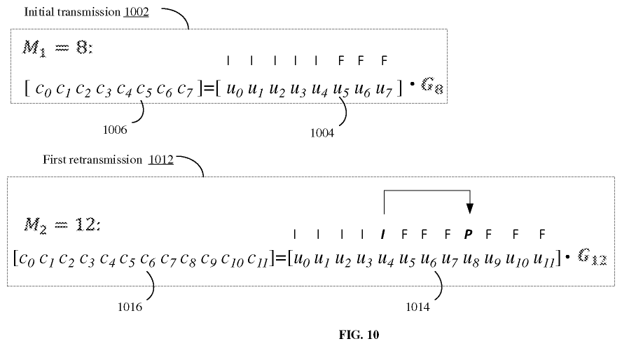

For example, the initial transmission is a (M₁=8, K=5) polar code, where {u₀, u₁, u₂, u₃, u₄} is the information set, and {u₅, u₆, u₇} is the frozen set. Its encoding process is illustrated in FIG. 10.

As shown in FIG. 10, in the encoding process for the initial transmission 1002, the bit vector 1004 contains the information bits (indicated by I) in the most reliable bit positions and the frozen bits (indicated by F) in the least reliable bit positions. The bit vector 1004 is multiplied by the polar transformation matrix G₈ to generate the code vector 1006.

In the first retransmission, four additional code bits are transmitted. These four bits are coupled with the initially transmitted 8 bits to form a (M₂=12, K=5) polar code. The coupling is achieved by copying the value of u₄ to u₈ during encoding, thus generating a PC function u₄+u₈=0 (or equivalently u₈=u₄). As said, the largest index in this PC function corresponds to the PC bit (here u₈). During decoding, u₄ decoded as an information bit, while u₈ is decoded as a PC bit using u₈=u₄. With {u₀, u₁, u₂, u₃, u₄} as the information set, {u₈} as the PC set, and {u₅, u₆, u₇, u₉, u₁₀, u₁₁} as the frozen set, the encoding process is illustrated in FIG. 10.

As shown in FIG. 10, in the encoding process for the first retransmission 1012, the bit vector 1014 contains the information bits and frozen bits of the initial bit vector 1004, coupled to four addition bits, where one of the information bits (namely u₄) is copied to one of the added bits (namely u₈) that is used as a PC bit (indicated by P). The bit vector 1014 is multiplied by the polar transformation matrix G₁₂ to generate the code vector 1016.

In the second retransmission, the remaining four bits c₁₂, c₁₃, c₁₄, c₁₅ are transmitted to form a (M₃=16, K=5) polar code. But this time no new PC bits are generated.

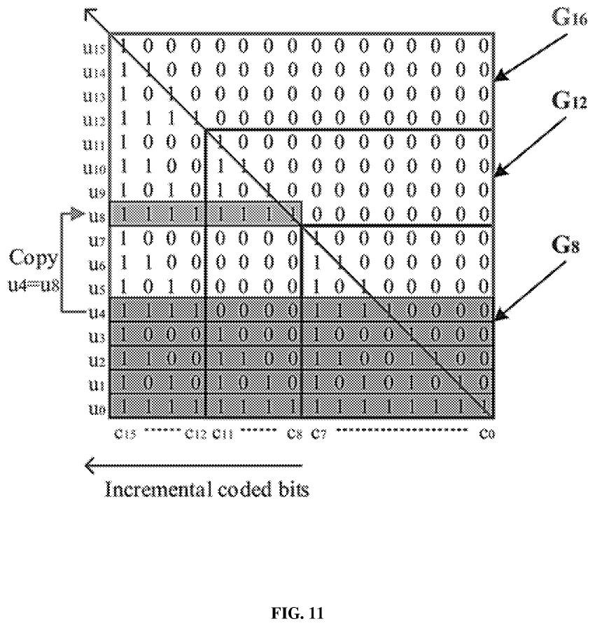

From the polar transform matrix point of view, the three transmissions with effective code lengths M₁=8, M₂=12, M₃=16, are illustrated in FIG. 11.

FIG. 11 illustrates examples of the G₈, G₁₂ and G₁₆ polar transformation matrices that may be used to perform the encoding of the initial transmission, first retransmission and second retransmission as described above. Notably, the G₁₂ and G₁₆ polar transformation matrices cause the value of u₄ to be copied to u₈ during encoding.

Rate-compatible LDPC coding is also another desirable technology for wireless applications. LDPC rate matching may involve a combination of puncturing, shortening, and repetition used together with quasi-cyclic lifting based on a base graph (BG) and a set of shifting values. In particular examples, the lifting size Z_{c} is grouped into eight sets according to Z_{c}=αⱼ×2^{k}ⱼ, where αⱼ∈{2,3,5,7,9,11,13,15} and max (kⱼ)∈{7,7,6,5,5,5,4,4}. The lifting sizes derived from the same αⱼ belong to the same set, and share the same shifting value. The shifting values for all the non-zero positions in the BG and for all groups of lifting sizes are stored in a single table. During the construction of a PC matrix, the lifting size Z_{c}, is determined first, then the set index j of the lifting size is obtained, and finally the shifting value is obtained from the table.

In general, a PC polar code scheme may need to specify the following parameters:
Whether to perform PC encoding for polar codes.
What parts of a codeword is PC encoded.
Specific PC encoding methods.

Some embodiments of the present disclosure include methods to perform PC encoding first, and then perform polar encoding. The methods also support IR-HARQ retransmission for both LDPC and polar codes. Some embodiments of the present disclosure may include the following objectives:
To obtain a stable performance under a wide range of code lengths and rates.
To support multiple transmissions and retransmissions, e.g., with multiple redundancy versions.

Methods in accordance with embodiments of the present disclosure may include one or more of the following features:
Methods to determine whether and how to perform PC encoding:
   Whether to perform PC encoding according to physical channel types and/or code parameters and/or application scenarios.
   How to perform PC encoding (for example, mark frozen bits as PC bits).
Methods to perform PC encoding for different parts of the code:
   Methods to perform subblock-wise PC encoding.
   Different subblocks of the code.
   Different redundancy versions and transmissions.

Some embodiments of the present disclosure include one or more of the following features, which can be separately adopted, or work together as a complete solution.

A first aspect of the present disclosure relates to methods to determine whether to perform PC encoding, including one or more of the following features:
rules to specify whether to perform PC encoding according to physical channel types;
rules to specify whether to perform PC encoding according to code parameters;
rules to specify whether to perform PC encoding according to both physical channel types and code parameters;
rules to specify whether to perform PC encoding according to application scenarios and priority;
rules to specify different ways to perform PC encoding and which way to select in different physical channels and coding parameters.

A second aspect of the present disclosure relates to methods to perform PC encoding for different parts of the code. The methods may include one or more of the following configurations:
Apply PC-encoding to different subblocks of the code;
Apply PC-encoding to different redundancy versions and transmissions.

PC polar coding is an effective way to enhance coding performance. Similar schemes such as polarization-adjusted convolutional (PAC) codes, also apply an outer convolutional code (CC) before the polar encoding step, in order to boost performance. These PC-polar, PAC and other methods that generate assistant bits from the information block before polar encoding all belong to the same category. The general term may be called “assistant-bit-based polar coding”. However, for convenience, the various assistant-bit-based polar coding schemes may be referred to herein simply as PC-polar codes.

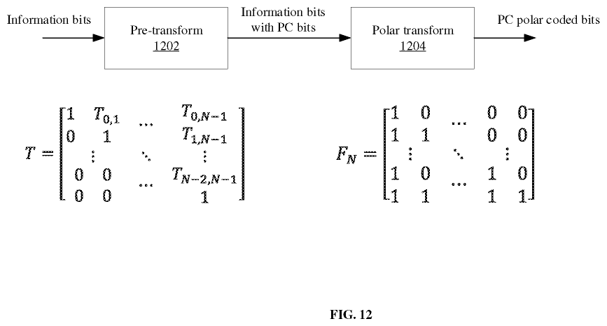

PC-polar, PAC, and other assistant-bit-based polar coding designs can be generalized to the framework of a pre-transformation matrix, in which a pre-transformation step is performed before polar encoding. The pre-transformation step involves multiplying the input vector by an upper-triangular matrix, as illustrated in FIG. 12.

In the example of FIG. 12, information bits are transformed by a pre-transformation matrix 1202 to generate information bits with PC bits. The information bits with PC bits are then encoded by a polar transformation matrix 1204 (also referred to as simply “polar matrix”) to generate the PC polar coded bits (also referred to as pre-transformed polar codes). FIG. 12 illustrates examples of the pre-transformation matrix 1202, denoted T, and the polar transformation matrix 1204, denoted F_{N}.

Mathematically, pre-transformed polar codes are defined by a generator matrix G_{N}=T×F_{N}, where T is the upper-triangular pre-transformation matrix, shown below.

$$T = [ \begin{matrix}\begin{matrix}\begin{matrix}1 & {T}_{0 , 1}\end{matrix} \\ \begin{matrix}0 & 1\end{matrix}\end{matrix} & … & \begin{matrix}{T}_{0 , N - 1} \\ {T}_{1 , N - 1}\end{matrix} \\ ⋮ & ⋱ & ⋮ \\ \begin{matrix}\begin{matrix}0 & 0\end{matrix} \\ \begin{matrix}0 & 0\end{matrix}\end{matrix} & … & \begin{matrix}{T}_{N - 2 , N - 1} \\ 1\end{matrix}\end{matrix} ]$$

And F_{N} is the polar matrix, shown below.

$${F}_{N} = [ \begin{matrix}\begin{matrix}\begin{matrix}1 & 0\end{matrix} \\ \begin{matrix}0 & 1\end{matrix}\end{matrix} & … & \begin{matrix}\begin{matrix}0 & 0\end{matrix} \\ \begin{matrix}0 & 0\end{matrix}\end{matrix} \\ ⋮ & ⋱ & ⋮ \\ \begin{matrix}\begin{matrix}1 & 0\end{matrix} \\ \begin{matrix}1 & 0\end{matrix}\end{matrix} & … & \begin{matrix}\begin{matrix}1 & 0\end{matrix} \\ \begin{matrix}1 & 1\end{matrix}\end{matrix}\end{matrix} ]$$

The encoding process can be expressed as

$${c}_{0}^{N - 1} = {u}_{0}^{N - 1} {G}_{N} = {u}_{0}^{N - 1} {TF}_{N} = {v}_{0}^{N - 1} {F}_{N}$$

where

$${u}_{0}^{N - 1}$$

is a length-N vector, whose indices corresponding to information bit positions are assigned values of the information bits (or payload bits), and the indices corresponding to frozen bit positions are assigned pre-defined values (typically zero, i.e., u_{F}=0). After PC encoding (or pre-transformation), a length-N vector

$${v}_{0}^{N - 1}$$

is obtained, which may contain both information bits and PC bits, or only PC bits.

When the PC codes (or pre-transformation codes defined by T the upper-triangular pre-transformation matrix) is a systematic code, the vector

$${v}_{0}^{N - 1}$$

contains both information bits and PC bits;

When the PC codes (or pre-transformation codes defined by T the upper-triangular pre-transformation matrix) is a non-systematic code, the vector

$${v}_{0}^{N - 1}$$

contains only PC bits;

Usually, to facilitate hardware implementation, the PC encoding (or pre-transformation encoding), i.e., multiplying by the pre-transformation matrix T, is described and implemented by a set of shift registers (e.g., the PC-polar encoding shift registers described above), with wiring and connections and output defined by a polynomial. The set of shift registers may together be referred to as a shift register (where each element in the shift register may be a single register (i.e., a 1-bit register)). A shift register (which may be referred to as a set of shift registers) in which the elements (which are single registers in the set of shift registers) are connected in a cyclical manner (i.e., the highest index element has a connection to the lowest index element) may be referred to as a cyclic shift register or a set of cyclic shift registers. The input is fed into the shift registers, and the values in the registers are shifted (or cyclic shifted) by one position after each information and/or frozen bit position in the length-N vector. The output can be taken from the values stored in the shift registers.

It should be understood that the use of a shift register (or cyclic shift register) is an example implementation for a cyclic shift operation that is used in PC-polar encoding as disclosed herein. In various examples, the cyclic shift operation may be implemented using hardware (e.g., using shift registers) or may be implemented using software (e.g., logic). Some implementations of the cyclic shift operation may use a hash function or a lookup table, for example. Various software and/or hardware implementations of the cyclic shift operation may be possible within the scope of this disclosure.

In some cases, even with the addition PC bits to the polar code, CRC bits may still be required for error detection. Therefore, the code may also be known as “PC-CA-polar codes”.

For simplicity, PC-polar codes may be used herein to refer to all the concatenated polar codes that involves PC outer coding that generate PC bits (such as those in the vector

$${v}_{1}^{N}$$

) before polar encoding.

For generality, PC-polar codes may be used herein to refer to all the concatenated polar codes that fall into the pre-transformation polar code framework.

Polar code may be adopted as the channel coding scheme for various scenarios, which require a wide range of code lengths and rates. As a result, a configuration is required to specify where and when to apply PC polar codes.

A first aspect of the present disclosure relates to methods to determine whether to perform PC encoding;

The method may include one or more rules to specify whether to perform PC encoding according to physical channel types;
According to the physical channel type and uplink/downlink traffic, determine whether to apply PC encoding.
One configuration may be: adopt PC-polar coding for physical uplink control channel (PUCCH) that carries uplink control information (UCI) content including HARQ feedback (ACK/NACK) and scheduling request (SR) and adopt non-PC-polar coding for all other physical channels;
One configuration may be: adopt PC-polar coding for PUCCH that carries UCI content including channel state information (CSI) and adopt non-PC-polar coding for all other physical channels;
One configuration may be: adopt PC-polar coding for PUCCH that is not multiplexed on physical uplink shared channel (PUSCH) and adopt non-PC-polar coding for all other physical channels;
Another configuration may be: adopt PC-polar coding for PUCCH (including those multiplexed on PUSCH) and adopt non-PC-polar coding for all other physical channels; Another configuration may be: adopt PC-polar coding for PUCCH and PBCH and adopt non-PC-polar coding for all other physical channels;
Another configuration may be: adopt PC-polar coding for PUCCH and PDCCH and adopt non-PC-polar coding for all other physical channels;
Another configuration may be: adopt PC-polar coding for PUCCH and PBCH and PDCCH and adopt non-PC-polar coding for all other physical channels;
Another configuration may be: adopt PC-polar coding for stage-1 PDCCH and adopt non-PC-polar coding for stage-2 PDCCH; The above configurations' advantages are enhanced performance for shorter polar codes.
Another configuration may be: adopt PC-polar coding for all control channels (PUCCH and PBCH and PDCCH) and adopt non-PC-polar coding for all data channels (PUSCH, PDSCH);
Another configuration may be: adopt PC-polar coding for all uplink channels (PUCCH and PUSCH) and adopt non-PC-polar coding for all downlink channels (PBCH, PDCCH, and PDSCH); The above configurations' advantages are unified designs for simpler description and enhanced performance for shorter polar codes.

The method may include one or more rules to specify whether to perform PC encoding according to code parameters;
According to the coding parameters, determine whether to apply PC encoding.
One configuration may be: adopt PC-polar coding for code length up to N_{max,pc}, where N_{max,pc} can be 32, 64, 128, 256, 512, 1024;
One configuration may be: adopt PC-polar coding for information block length up to K_{max,pc}, where K_{max,pc} can be 11, 16, 19, 22, 24, 32, 64, 128, 256, 512;
Another configuration may be: adopt PC-polar coding for code rates up to R_{max,pc}, where R_{max,pc} can be ¾, ⅔, ½, ⅖, ⅜, ¼, ⅛.

Another configuration may be: adopt PC-polar coding for cases with code length up to N_{max,pc}, and code rates up to R_{max,pc}, satisfied at the same time. The values of N_{max,pc} and R_{max,pc} can be chosen from the above-mentioned values;

The method may include one or more rules to specify whether to perform PC encoding according to both physical channel types and code parameters;
According to both physical channel type and uplink/downlink traffic, and the coding parameters, to determine whether to apply PC encoding.
One configuration may be: adopt PC-polar coding for PUCCH with code length up to N_{max,pc}, where N_{max,pc} can be 32, 64, 128, 256, 512, 1024;
One configuration may be: adopt PC-polar coding for PUCCH with information block length up to K_{max,pc}, where K_{max,pc} can be 11, 16, 19, 22, 24, 32, 64, 128, 256, 512;
One configuration may be: adopt PC-polar coding for stage-2 PDCCH with length up to N_{max,pc}, where N_{max,pc} can be 32, 64, 128, 256, 512, 1024;

The method may include one or more rules to specify whether to perform PC encoding according to application scenarios and priority;

According to application scenarios, determine whether to apply PC encoding.

In some embodiments, adopt PC-polar coding for ultra-reliable low-latency communication (URLLC) traffic and adopt non-PC-polar coding for all other physical channels. In practice, the standard specification may not explicitly mention URLLC, but may associate PC-polar coding with traffics with certain priority index (indices), such as the high-priority (HP) UCI content, or high-priority data traffics.

The method may include one or more rules to specify different ways to perform PC encoding and which way to select in different physical channels and coding parameters. There may be two types of PC encoding methods. One is using a pre-defined number of PC bits, e.g., 3 bits or 6 bits or 8 bits. This can be called type-I PC-polar. The other is using all frozen bits as PC bits. This can be called type-II PC-polar.

In some embodiments, type-I polar may be used for PUCCH with code length up to N_{max,pc}, where N_{max,pc} can be 32, 64, 128, 256, 512, 1024; type-II polar may be used for PUCCH with code length larger than N_{max,pc}.

In some embodiments, type-I polar may be used for PUCCH with information block length up to K_{max,pc}, where K_{max,pc} can be 11, 16, 19, 22, 24, 32, 64, 128, 256, 512; type-II polar may be used for PUCCH with information block length larger than K_{max,pc}.

In some embodiments, type-I polar may be used for PUCCH; In some embodiments, type-II polar may be used for PDCCH and/or PBCH.

A second aspect of the present disclosure relates to methods to perform PC encoding for different parts of the code.

Aspects of the present disclosure may also relate to partial PC-polar coding schemes, as well as segmented PC-polar schemes.

In an example PC-polar encoding method, the PC encoding is applied to all information bits before a PC bit is generated. A variation on this scheme can apply PC encoding specifically to parts of the information bits. The benefits of this variation can be simplified implementation or compatibility with other coding features in the encoding chain.

The PC encoding can be applied to certain subblocks of the polar code. Thus, PC-encoding can be restricted to within some length-power-of-2 subblock(s), while other subblock(s) may follow non-PC-encoding methods.

For example, the length-N vector

$${u}_{0}^{N - 1} ,$$

whose indices corresponding to information bit positions are assigned values of the information bits (or payload bits), and the indices corresponding to frozen bit positions are assigned pre-defined values (typically zero, i.e., u_{F}=0), can be represented as the concatenation of two subblocks, i.e.,

$${u}_{1}^{N} = [ {u}_{0}^{N / 2 - 1} , {u}_{N / 2}^{N - 1} ] .$$

In one configuration, only the first subblock is PC-encoded. The PC-encoding matrix (or pre-transformation matrix) can be represented as

$$T = [ \begin{matrix}{T}_{0} & 0 \\ 0 & I\end{matrix} ] ,$$

where T₀ is an N/2-by-N/2 upper-triangular submatrix, and I is an N/2-by-N/2 identity submatrix. The encoding process is still

$${c}_{0}^{N - 1} = {u}_{0}^{N - 1} {TF}_{N} = {v}_{0}^{N - 1} {F}_{N} .$$

However, it is clear that

$${v}_{0}^{N - 1} = [ {v}_{0}^{N / 2 - 1} , {v}_{N / 2}^{N - 1} ] = [ {u}_{0}^{N / 2 - 1} \times {T}_{0} , {u}_{N / 2}^{N - 1} ] .$$

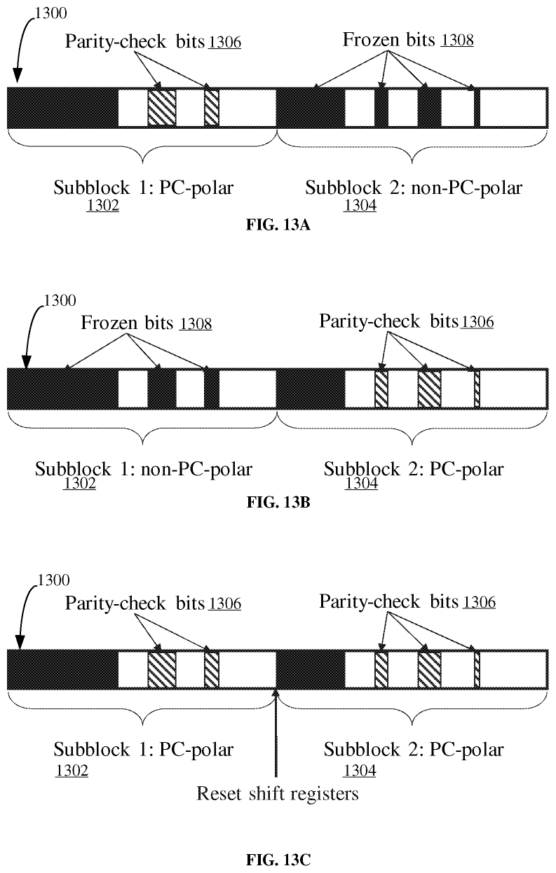

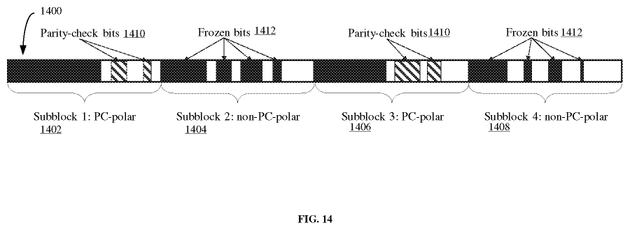

As seen, only the first half of the code is PC-encoded, and the second half is not affected by PC encoding. The configuration is illustrated in FIG. 13A.

FIG. 13A illustrates an example of a polar codeword 1300 that is logically divided into two subblocks referred to as a first subblock 1302 (or subblock 1) and a second subblock 1304 (or subblock 2). The terms “first” or “second” subblock are not intended to be limited to a particular order within the codeword 1300. In some examples, the first subblock 1302 may be transmitted earlier than the second subblock 1304 (thus “first” and “second” may refer to a transmission order), but this is not a requirement or intended limitation. It should be understood that the codeword 1300 is shown with two subblocks 1302, 1304 for simplicity. In general, a polar codeword may have two or more subblocks, and PC encoding may be used (or not used) to generate each subblock independently of any other subblock. That is, PC encoding used for one subblock does not necessarily influence or depend on whether PC encoding is used (or not used) for another subblock of the codeword 1300. A polar codeword may be divided into two or more subblocks in any suitable manner, such as those disclosed herein, and the subblocks may be equal or unequal in length. In the example of FIG. 13A, the first subblock 1302 is generated by applying PC encoding to the information bits corresponding to the first subblock 1302 to generate PC bits, followed by polar encoding to arrive at the PC-polar encoded subblock 1302 (where PC bits 1306 are in place of frozen bits in some frozen bit positions; although not shown, other frozen bit positions may have frozen bits); and second subblock 1304 is generated by polar encoding the information bits corresponding to the second subblock 1304 (without PC encoding) to arrive at the non-PC-polar encoded subblock 1304 (with only frozen bits 1308 in frozen bit positions).

In another configuration, only the second subblock is PC-encoded. The PC-encoding matrix (or pre-transformation matrix) can be represented as

$$T = [ \begin{matrix}I & 0 \\ 0 & {T}_{1}\end{matrix} ] ,$$

where T₁ is an N/2-by-N/2 upper-triangular submatrix, and I is an N/2-by-N/2 identity submatrix. The encoding process is still

$${c}_{0}^{N - 1} = {u}_{0}^{N - 1} {TF}_{N} = {v}_{0}^{N - 1} {F}_{N} .$$

However, it is clear that

$${v}_{0}^{N - 1} = [ {v}_{0}^{N / 2 - 1} , {v}_{N / 2}^{N - 1} ] = [ {u}_{0}^{N / 2 - 1} , {u}_{N / 2}^{N - 1} \times {T}_{1} ] .$$

As seen, only the second half of the code is PC-encoded, and the first half is not affected by PC encoding.

An example is illustrated in FIG. 13B. Again, the polar codeword 1300 is logically divided into first and second subblocks 1302, 1304. In this example, the first subblock 1302 is generated by polar encoding the information bits corresponding to the first subblock 1302 (without PC encoding) to arrive at the non-PC-polar encoded subblock 1302 (with only frozen bits 1308 in frozen bit positions); and the second subblock 1304 is generated by applying PC encoding to the information bits corresponding to the second subblock 1304 to generate PC bits, followed by polar encoding to arrive at the PC-polar encoded subblock 1304 (where PC bits 1306 are in place of frozen bits in some frozen bit positions; although not shown, other frozen bit positions may have frozen bits).

In another configuration, both the first and second subblocks are PC-encoded. The PC-encoding matrix (or pre-transformation matrix) can be represented as

$$T = [ \begin{matrix}{T}_{0} & 0 \\ 0 & {T}_{1}\end{matrix} ] ,$$

where T₀ and T₁ are N/2-by-N/2 upper-triangular submatrices. The encoding process is still

$${c}_{0}^{N - 1} = {u}_{0}^{N - 1} {TF}_{N} = {v}_{0}^{N - 1} {F}_{N} .$$

However, it is clear that

$${v}_{0}^{N - 1} = [ {v}_{0}^{N / 2 - 1} , {v}_{N / 2}^{N - 1} ] = [ {u}_{0}^{N / 2 - 1} \times {T}_{0} , {u}_{N / 2}^{N - 1} \times {T}_{1} ] .$$

As seen, both the first half and second half of the code are PC-encoded. However, compared to methods that PC encode all information bits, this method is different in that the PC encoding between the first subblock and the second subblock are independent. The PC bits (i.e., the values of the bits) in the second half will not depend on the first half. This decoupled PC encoding method may be beneficial for self-decodability in the cases where the two subblocks of a polar code need to be decoded independently without receiving the coded bits (signals) from another subblock. IR-HARQ may be an example of such a case.

As said, in an example hardware implementation, the PC encoding (or pre-transformation encoding), i.e., multiplying by the pre-transformation matrix T, is described and implemented by a set of shift registers, with wiring and connections and output defined by a polynomial. This means that before encoding into a new subblock, the values stored in the shift registers need to be cleared (or the shift registers need to be reset) to remove the coupling effect between subblocks. While a single PC polynomial may be more convenient for both description and implementation, different polynomials for PC encoding can be implemented for different subblocks as a result of decoupling the subblocks (i.e., making the PC encodings of the subblocks independent). This configuration, along with the shift register resetting, is illustrated in FIG. 13C.

In FIG. 13C, the codeword 1300 is again logically divided into first and second subblocks 1302, 1304. In this example, PC encoding is applied to the information bits corresponding to the first subblock 1302 to generate a first set of PC bits and PC encoding is applied to the information bits corresponding to the second subblock 1304 to generate a second set of PC bits, followed by polar encoding, such that the first subblock 1302 is a PC-polar encoded subblock (with PC bits 1306 in place of frozen bits in some frozen bit positions; although not shown, other frozen bit positions may have frozen bits) and the second subblock 1304 also is a PC-polar encoded subblock (with PC bits 1306 in place of frozen bits in some frozen bit positions; although not shown, other frozen bit positions may have frozen bits). It should be noted that the first set of PC bits in the first subblock 1302 is generated using only information bits of the first subblock 1302 and the second set of PC bits in the second subblock 1304 is generated using only information bits of the second subblock 1304. To enable the same set of shift registers to be used for PC encoding of both the first and second subblocks 1302, 1304, the shift registers may be reset between the end of PC encoding of the first subblock 1302 and the start of PC encoding of the second subblock 1304 (e.g., as indicated in FIG. 13C). This may enable PC encoding to be achieved using a smaller set of shift registers (e.g., the shift registers only need to hold the length of the information bits in the subvector corresponding to one subblock 1302, 1304, rather than the full length of the bit vector for the code 1300) as well as enabling reuse of the same set of shift registers, thus enabling savings in computing resources (e.g., savings in chip area, memory resources, etc.).

The reset of the shift registers between PC encoding of the first and second subblocks 1302, 1304 also helps to decouple the first and second sets of PC bits, meaning that the first subblock 1302 can be decoded with assistance from the first set of PC bits (without requiring the second set of PC bits) and the second subblock 1304 can be decoded with assistance from the second set of PC bits (without requiring the first set of PC bits). As discussed elsewhere in this application, the decoupling of the first and second sets of PC bits may provide technical advantages in that if only one PC-polar encoded subblock of a PC-polar codeword is received at a receiver, the receiver can still successfully recover the information bits without requiring the remaining subblocks of the PC-polar codeword to be received. This may enable more flexible and/or more robust wireless communications, as well as possible saving of computing resources at the decoder.

The above design can also be generalized to arbitrary subblocks. For example, assume there are S subblocks, a subset of the subblocks can be selected to perform PC encoding. At the beginning of each subblock, PC encoding is started, by resetting the shift registers in the corresponding description and implementations, and terminated at the end of a subblock. Multiple subblocks can be bundled for one instance of PC encoding. Therefore, the length of a subvector in

$${u}_{0}^{N - 1}$$

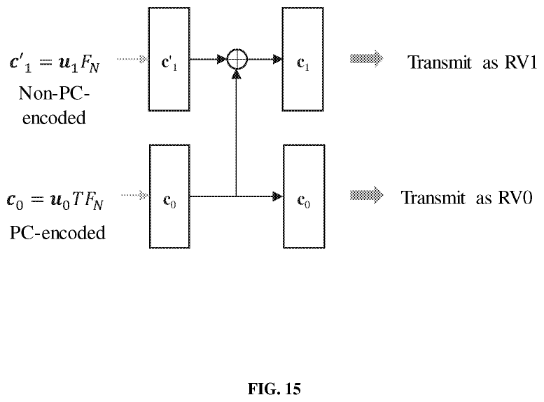

can be power-of-two, or multiples of power-of-two. An example is illustrated in FIG. 14.

FIG. 14 illustrates an example in which a polar codeword 1400 has an arbitrary number of subblocks (e.g., four subblocks 1402, 1404, 1406 and 1408). Each subblock may be generated from a respective subvector of the bit vector, where PC encoding may be independently used (or not used) in generation of each subblock. In the example shown, PC encoding is used in the generation of the first subblock 1402 and third subblock 1406 (such that PC bits 1410 are found in some of the frozen bit positions), while PC encoding is not used in the generation of the second subblock 1404 and fourth subblock 1406 (such that all frozen bit positions contain frozen bits 1412). As discussed above, where a set of shift registers is used to perform PC encoding, the set of shift registers may be reset between PC encoding of different subblocks (e.g., the shift registers may be cleared at the start of PC encoding of any subblock; or the shift registers may be cleared at the end of PC encoding of any subblock). In other examples, the PC encoding may be performed by implementing a cyclic shift operation in other ways instead of using shift registers. For example, if the cyclic shift operation in PC encoding is implemented using logic, instead of resetting the shift registers between PC encoding of different subblocks, reinitialization of the logic (e.g., reinitializing variables to zero) may be performed. Although an alternating pattern of PC-polar and non-PC-polar subblocks is illustrated in FIG. 14, this is only exemplary. For example, a device or apparatus may be configured to use or not use PC encoding for a subblock based on various settings and/or criteria, some of which are discussed herein.

Embodiments of the present disclosure may include one or more of the following configurations.

Apply PC-encoding to different subblocks of the code, where:
Divide code into S subblocks of length power-of-2, and apply PC encoding to the first S′ subblocks, and S′<S. Specifically, S′ can be 1,2,4. The benefit is that more frozen bits can be used as PC bits, and thus more coding gain.
Divide code into S subblocks of length power-of-2, and apply PC encoding to the first S′ subblocks that has information bits, and S′<S. Specifically, S′ can be 1,2,4. The reason is that only the frozen bits after the first information bit can become PC bits.
Divide code into S subblocks of length power-of-2, and apply PC encoding to the last S′ subblocks, and S′<S. Specifically, S′ can be 1,2,4. The benefit is that weight spectrum can be improved most by PC encoding the last subblocks.
Divide code into S subblocks of length power-of-2, and apply PC encoding to the all S subblocks. However, each subblock is PC encoded independently or separately. That is, the PC bits in a subblock are the parity bits of information bits only in that subblock. In other words, the PC bits in a subblock only check the information bits in the same subblock. The benefit is that subblock-wise SCL decoding can be employed to reduce memory usage.

When IR-HARQ is employed for polar codes, several shorter polar codes can be further combined and polarized into a longer polar code. As illustrated in FIG. 15, two shorter polar codes c₀ and c′₁ are further polarized to generate c₀ and c₁, where c₀ remains unchanged and c₁=C₀ ⊕c′₁. For IR-HARQ applications, c₀ can be transmitted in the initial transmission, as a redundancy version 0 (RV0), and c₁ can be transmitted in the subsequent retransmission, as another redundancy version, RV1. In one implementation, PC encoding may be performed for RV0 only, and PC encoding may not be performed for RV1. That is, c₀ is generated by c₀=u₀TF_{N}, in which the input vector u₀ is multiplied by the PC encoding matrix T (or the upper-triangular pre-transformation matrix T) before multiplying with the polar matrix F_{N}; and c′₁ is generated directly by c′₁=u₁F_{N}, in which the input vector u₁ is directly multiplied by the polar matrix F_{N}.

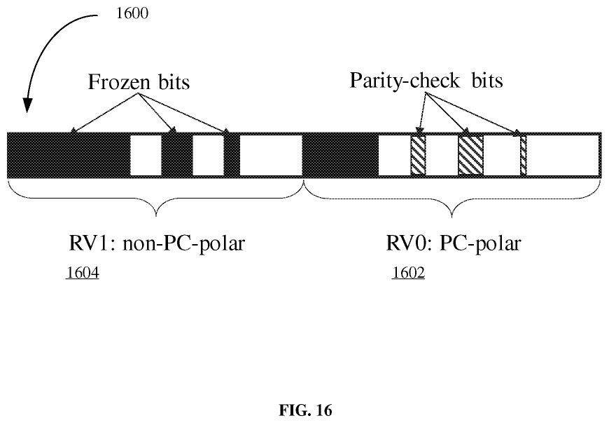

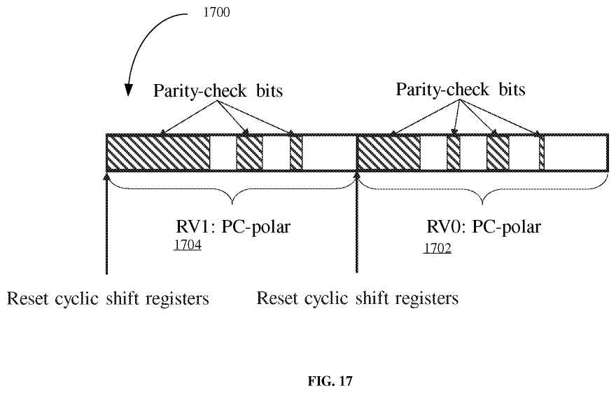

PC-encoding may be applied to different redundancy versions and transmissions.
In some embodiments, apply PC-encoding only to the first redundancy version, and do not perform PC-encoding for the remaining redundancy versions. An illustration is given in FIG. 16. FIG. 16 illustrates an example code 1600 that has been divided into two subblocks. One subblock 1602 is transmitted as an initial transmission (first redundancy version, denoted RV0) and has PC encoding applied, while a second subblock 1604 that is transmitted as a subsequent retransmission (remaining redundancy version, denoted RV1) does not have PC encoding applied.
In some embodiments, apply PC-encoding only to the first S′ redundancy version, where S′<S and S is the total number of redundancy versions, and do not perform PC-encoding for the remaining redundancy versions.
In some embodiments, apply PC-encoding to the redundancy versions, in which the transmission lengths of the redundancy versions are pre-defined or fixed.
In some embodiments, apply PC-encoding to the redundancy versions used for the retransmissions and/or repetitions for PUCCH/UCI and/or PDCCH/DCI. For PUCCH/UCI and/or PDCCH/DCI retransmissions or repetitions, each redundancy version is a self-decodable shorter codeword, and when soft combined, produce a longer codeword for higher coding gain. For each of the self-decodable shorter codewords, PC encoding is performed independently and separately, allowing self-decodability in the absence of other redundancy versions. An illustration is given in FIG. 17. In the example of FIG. 17, shorter codewords 1702, 1704 (corresponding to redundancy versions RV0 and RV1, respectively) are soft combined to obtain a longer codeword 1700. Each of the shorter codewords 1702, 1704 may be independently and separately PC-encoded. The set of shift registers used for PC encoding are reset between PC encoding of different shorter codewords, as indicated in FIG. 17.
In some embodiments, if a redundancy version is defined such that it is transmitted in a single transmission, PC encoding can be applied to this redundancy version. Otherwise. If multiple transmissions are allowed within one redundancy version, that redundancy version should not be PC encoded.
Alternatively, if a redundancy version is defined such that multiple transmissions are allowed within one redundancy version and PC encoding is performed for this redundancy version, then the code bits associated with each individual transmission should be independently or separately PC encoded.

Some embodiments of the present disclosure additionally relate to determining the number of so-called special assistant bits

$${n}_{PC}^{wm} .$$

Special assistant bits may be known by or referred to with different names.

The assistant bits can be considered “special” in the sense that they are PC bits that are not selected according to reliability order, or not selected only according to reliability order.

For example, the assistant bits can be PC bits with minimum row weight in the non-frozen bit set. The non-frozen bit set may be the K+J most reliable bit positions (excluding those bit positions corresponding to punctured or shortened bit positions), where K is the number of information bits, and J is the number of assistant bits.

The number of special assistant bits

$${n}_{PC}^{wm}$$

can be given by a table depending on the rate matching output sequence length E and the information block length K, as illustrated in the following table.

TABLE 1

| | | | |
|---|---|---|---|
| E\K | Kₘᵢₙ | ... | Kₘₐₓ |
| Eₘᵢₙ | ${n}_{PC , 1 , 1}^{wm}$ | ... | ${n}_{PC , 1 , y}^{wm}$ |
| ... | ... | ... | ... |
| Eₘₐₓ | ${n}_{PC , x , 1}^{wm}$ | ... | ${n}_{PC , x , y}^{wm}$ |

The number of special assistant bits

$${n}_{PC}^{wm}$$

can be given by a piecewise function, i.e.,

$${n}_{PC}^{wm} = func ( N , E , K ) or {n}_{PC}^{wm} = func ( E , K ) ,$$

in which the input parameters may include the rate matching output sequence length E and the information block length K, and even the mother code length N. For example,

$${n}_{PC}^{wm} = 0 when K \leq {c}_{1} or ( E - K \leq {c}_{2} ) , and {n}_{PC}^{wm} = {n}_{1}$$

otherwise, where c₁, c₂, and n₁ are constants, and in one example, set c₁=6, c₂=7 and n₁=4 or 8 or 16 or 20.

Some embodiments of the present disclosure include example methods expressed in the form of pseudocodes for PC encoding of a particular code. The polar code has length 2N, and supports retransmission with two redundancy versions. The encoded bits d_{N} d_{N+1} d_{N+2} . . . d_{2N-1} belong to RV0, for initial transmissions, and the input vector contains all the information bits. A parameter I_{PC}=1 indicates that PC encoding is enabled. The encoded bits d₀ d₁ d₂ . . . d_{N-1} belong to RV1, for retransmissions, and the input vector contains part of the information bits, whose values are assigned to two sets of information bit positions according to certain ordering. In RV1, PC encoding is not performed.

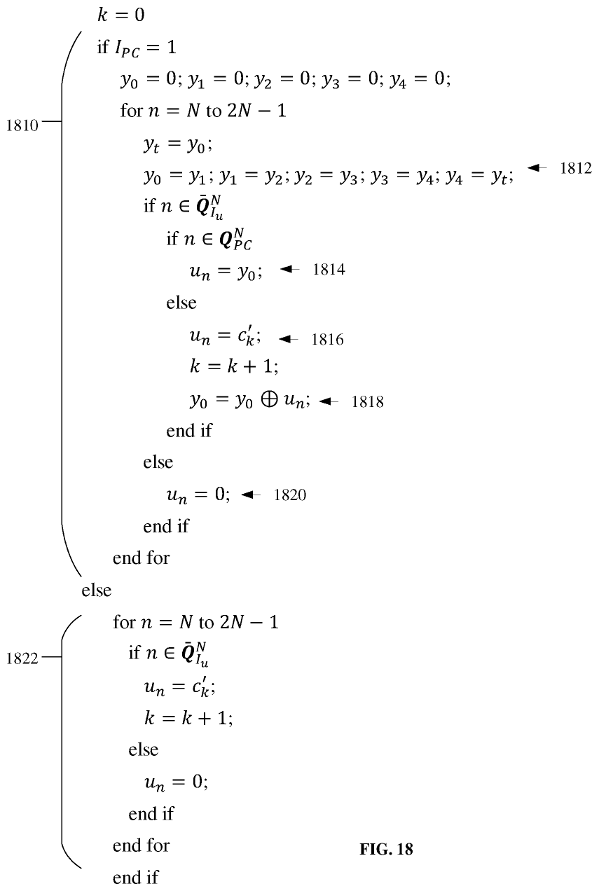

For the first redundancy version, generate uᵤ=[u_{N} u_{N+1} u_{N+2} . . . u_{2N-1}] according to the pseudocode shown in FIG. 18.

The pseudocode in FIG. 18 illustrates an example of how PC encoding may be applied. The output of the pseudocode is the PC-encoded vector of to-be-polar-coded bits uᵤ=[u_{N} u_{N+1} u_{N+2} . . . u_{2N-1}], which is then polar coded to obtain the final PC-polar codeword.

$${\overline{Q}}_{{I}_{u}}^{N}$$

denotes a first set of information bit positions (for uᵤ),

$${Q}_{PC}^{N}$$

denotes the set of re on positions, c′ denotes a bit sequence to be encoded, and ⊕ denotes the XOR operation. The bit sequence c′ may or may not be an interleaved bit sequence. The bit positions for information bits and PC bits (as defined by

$${\overline{Q}}_{{I}_{u}}^{N} and {Q}_{PC}^{N} ,$$

for example) may be selected or defined according to a standard, for example.

In FIG. 18, the pseudocode portion 1810 represents operations for applying PC-encoding (the parameter I_{PC}=1 indicates that PC encoding is enabled).

Line 1812 represents a cyclic shift operation for a length-5 array of elements, where bit values are stored in the elements {y₀, y₁, y₂, y₃, y₄}, and which is shifted by one each time. In this example, the input to the cyclic shift operation is at element y₀ and output from the cyclic shift operation is also at element y₀. It should be understood that the cyclic shift operation is not necessarily limited to a length of 5, and can be shifted in the direction of most significant bit (MSB) to least significant bit (LSB) or in the direction of LSB to MSB. The cyclic shift operation may be implemented in various ways, such as by using a cyclic shift register (e.g., as illustrated in FIG. 9), implemented by logic, using a hash function (e.g., a hash function that maps a 5-bit sequence to a bit value for a PC bit), using a lookup table (e.g., a lookup table that can be used to lookup a bit value for a PC bit based on a 5-bit sequence), or any other suitable hardware and/or software implementation.

In this example,

$${Q}_{PC}^{N}$$

is a subset of

$${\overline{Q}}_{{I}_{u}}^{N} .$$

For a current index, n is determined whether the index n is part of

$${\overline{Q}}_{{I}_{u}}^{N} .$$

If so, it is further determined if the index n is part of the PC bit set. If the index n is part of the PC bit set, the value of u_{N} is set to the output bit value of the cyclic shift operation (in this case, the output of the cyclic shift operation is at element y₀, as represented at line 1814), otherwise the value of u_{N} is set to the current information bit value (as represented at line 1816), the index of the information bits is increased by one, and the bit value of the information bit is inputted to the cyclic shift operation (in this case, the input of the cyclic shift operation is at element y₀, as represented at line 1818). If the index n is not part of

$${\overline{Q}}_{{I}_{u}}^{N} ,$$

it is assumed that the current index n belongs to the frozen bit set, and the value of u_{N} is set to the frozen bit value of 0 (as represented at line 1820).

The pseudocode portion 1822 represents operations for generating the output vector uᵤ=[u_{N} u_{N+1} u_{N+2} . . . u_{2N-1}] without PC encoding.

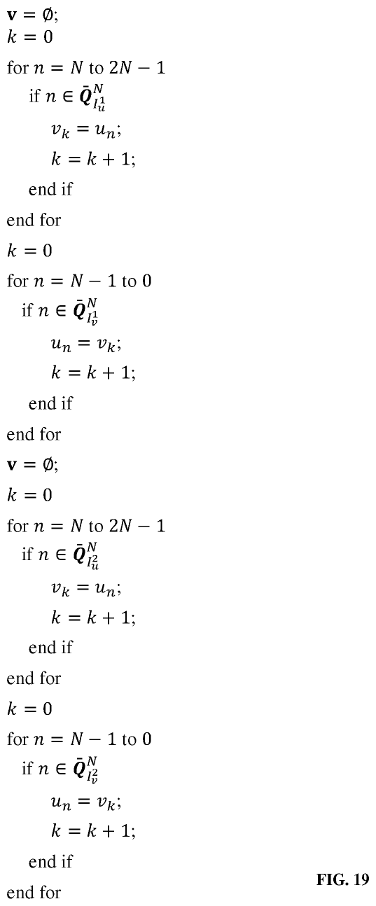

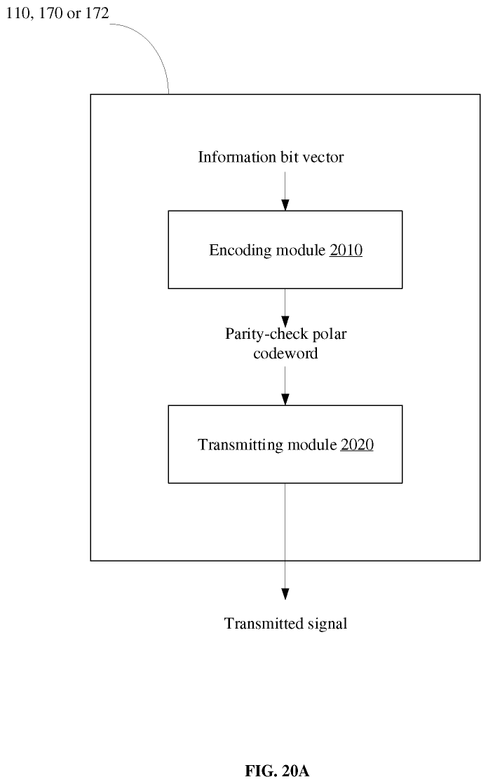

For the second redundancy version, generate uᵥ=[u₀ u₁ u₂ . . . u_{N-1}] according to the pseudocode shown in FIG. 19.

The pseudocode in FIG. 19 illustrates an example of how the vector of to-be-polar-coded bits uᵥ=[u₀ u₁ u₂ . . . u_{N-1}] may be generated, according to another set of information bit positions. There is no PC encoding applied in the pseudocode of FIG. 19.

The output bit vector u may be referred to as the vector of to-be-polar-coded bits, or the polar encoder input vector. That is, the polar matrix is applied to the vector u to obtain a polar codeword.

The output after encoding d=[d₀ d₁ d₂ . . . d_{2N-1}] is obtained by d=uF_{2N}, where F_{2N} is a 2N-by-2N polar matrix. The encoding is performed in GF(2).

The above descriptions be used to determine the one or more following PC-polar related parameters:
Whether to perform PC encoding for code block (CB) or transport block (TB).
Whether to perform PC encoding for a particular subblock or redundancy version or transmission.
Type of PC encoding adopted by a specific particular subblock or redundancy version or transmission;
Number of subblocks that has PC bits encoded from PC encoding.
The indices of subblocks that has PC bits encoded from PC encoding.

These parameters can either be pre-defined in standard specifications, or signaled using Radio Resource Control (RRC) messages or UCI.

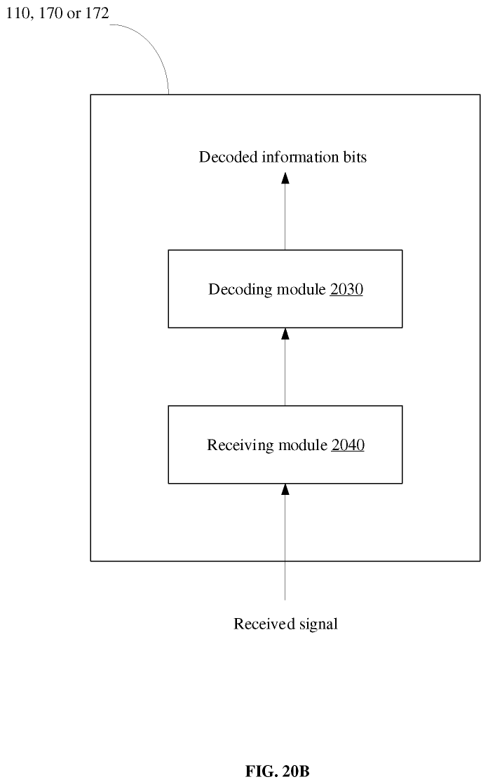

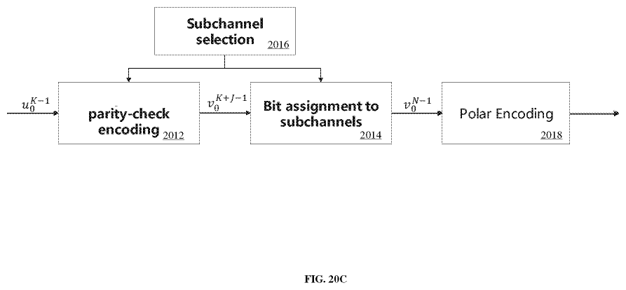

Reference is now made to FIGS. 20A-C. FIG. 20A illustrates an example device, such as the ED 110, T-TRP 170 and/or NT-TRP 172 previously described, including an encoding unit or module 2010 (generally referred to hereinafter as the encoding module 2010). The encoding module 2010 may be provided in addition to any one or more of the units or modules shown in FIG. 4, for example, however for simplicity not all units or modules of the device are shown in FIG. 20A. In some examples, the encoding module 2010 may be provided as a submodule of any of the units or modules previously described. Also shown in FIG. 20A is a transmitting unit or module 2020 (generally referred to hereinafter as the transmitting module 2020), which has been previously discussed with respect to FIG. 4.

The encoding module 2010 and/or transmitting module 2020 may be implemented as software, hardware or a combination of software and hardware. For example, the encoding module 2010 and/or transmitting module 2020 may be a circuit such as an integrated circuit. Examples of an integrated circuit includes a programmed FPGA, a GPU, or an ASIC. For instance, the encoding module 2010 and/or transmitting module 2020 may be at least partly implemented as logic, such as a logical function performed by a circuit, by a portion of an integrated circuit, or by software instructions executed by a processor, among other possibilities.

The encoding module 2010 and transmitting module 2020 may be used by a transmitting device to encode information bits of a bit vector into a PC polar codeword (e.g., using any of the examples of the present disclosure), and transmitting the PC polar codeword as a wireless communication signal over a communication channel.

In particular, the encoding module 2010 may encode the information bit vector into a PC polar codeword in which PC encoding is used on a subblock basis rather than on a codeword basis. Although not shown in FIG. 20A, the encoding module 2010 may include a PC-encoding submodule and a polar encoding submodule. The PC-encoding submodule may be used to generate a PC-encoded vector from the information bits of the information bit vector. As discussed elsewhere in this disclosure, a cyclic shift operation (which may be implemented using various hardware and/or software techniques, such as using a set of cyclically-connected shift registers (also referred to as a cyclic shift register), using a hash function, using a lookup table, using logic, etc.) may be used by the PC-encoding submodule to generate PC bits from information bits. The generated PC bits may be assigned to less reliable bit positions (e.g., frozen bit positions) of the PC-encoded vector while the information bits may be assigned to more reliable bit positions (e.g., information bit positions) of the PC-encoded vector. The polar encoding submodule may then be used to generate the PC polar codeword from the PC-encoded vector.

FIG. 20B illustrates another example device, which may be an instance of the ED 110, T-TRP 170 and/or NT-TRP 172 previously described, including a decoding unit or module 2030 (generally referred to hereinafter as the decoding module 2030). The decoding module 2030 may be provided in addition to any one or more of the units or modules shown in FIG. 4, for example, however for simplicity not all units or modules of the device are shown in FIG. 20B. In some examples, the decoding module 2030 may be provided as a submodule of any of the units or modules previously described. Also shown in FIG. 20B is a receiving unit or module 2040 (generally referred to hereinafter as the receiving module 2040), which has been previously discussed with respect to FIG. 4.

The decoding module 2030 and/or receiving module 2040 may be implemented as software, hardware or a combination of software and hardware. For example, the decoding module 2030 and/or receiving module 2040 may be a circuit such as an integrated circuit. Examples of an integrated circuit includes a programmed FPGA, a GPU, or an ASIC. For instance, the decoding module 2030 and/or receiving module 2040 may be at least partly implemented as logic, such as a logical function performed by a circuit, by a portion of an integrated circuit, or by software instructions executed by a processor, among other possibilities.

The decoding module 2030 and receiving module 2040 may be used by a receiving device to receive a wireless communication signal that contains at least one subblock of a PC polar codeword and to decode the subblock to recover the information bits encoded in the subblock. In particular, the decoding module 2030 may decode a subblock of a PC polar codeword using PC bits of that subblock, without requiring other subblocks of the PC polar codeword.

It should be understood that FIGS. 20A and 20B may represent the same device. That is, a single device may have the encoding module 2010, transmitting module 2020, decoding module 2030 and receiving module 2040. The device may perform encoding and transmitting when the device is in the role of a transmitting device, and may perform receiving and decoding operations when the device is in the role of a receiving device. In some examples, the encoding module 2010 and decoding module 2030 may be implemented together as an encoder/decoder module and the transmitting module 2020 and receiving module 2040 may be implemented together as a transceiver module.

FIG. 20C illustrates an example of an encoding chain that may be implemented by the encoding module 2010.

As previously mentioned, PC encoding may be implemented using a cyclic shift operation with a fixed length array of elements that is shifted by one each time. In some examples, a cyclic shift operation may be implemented using a set of shift registers (e.g., the PC-polar encoding shift registers described above) with wiring, connections and output that may be defined by a polynomial. In other examples, a cyclic shift operation may be implemented using logic. Some implementations of the cyclic shift operation may use a hash function or a lookup table to generate a PC bit for a given fixed-length sequence of prior information bits. Various software and/or hardware implementations of the cyclic shift operation may be possible within the scope of this disclosure.

As illustrated in FIG. 20C, the encoding process may be represented in three steps or stages.

The first step or stage is PC encoding 2012, in which a length-K bit vector (denoted

$${u}_{0}^{K - 1} )$$

is PC encoded to generate J assistant bits (or PC bits). The output of the PC encoding 2012 is a PC encoded vector of length K+J (denoted

$${v}_{0}^{K + J - 1} ) .$$

The operation of the PC encoding 2012 may be represented as follows:

$${v}_{0}^{K + J - 1} = {u}_{0}^{K - 1} {T}_{N}$$

In the above representation, the PC encoding is defined by a pre-transformation matrix T. In this example, the PC encoding can be defined by an upper-triangular pre-transformation matrix T. Using the cyclic shift operation described previously, each PC bit is generated based on preceding information bits of smaller indices. The PC encoding 2012 may be performed using a shift register, as previously described. A shift register may be, for example, a physical circuit or a logical shift register (e.g., implemented using software executed by a processor, for example as represented by the pseudocode described previously). In some examples, the PC encoding 2012 may be performed without using a shift register, for example using a hash function or look-up table to implement the pre-transformation matrix T. Other functional equivalents may be used within the scope of the present disclosure.

A subchannel selection module 2016 may instruct both the PC encoding 2012 and the subsequent bit assignment 2014. The number of assistant bits J, and where the assistant bits should be inserted into the bit vector, may be governed by the subchannel selection module 2016. The subchannel selection module 2016 outputs the several subchannel sets, which may be referred to as the information set Q_{I}, the PC set Q_{PC}, and the frozen set Q_{F}. The information set defines the information bit positions of the PC encoded vector, the PC set defines the PC bit positions of the PC encoded vector and the frozen set defines the frozen bit positions of the PC encoded vector. The information set, frozen set and PC set may be defined based on subchannel reliability (e.g., bit positions corresponding to more reliable subchannels may be defined to be part of the information set, while bit positions corresponding less reliable subchannels may be defined to be part of the frozen set or PC set). In some examples, the PC set may be a subset of the frozen set, meaning some frozen bit positions may be assigned to carry PC bits while other frozen bit positions still carry frozen bits. In some examples, all frozen bit positions may be permitted (or allowed) to be assigned PC bits (this may be referred to as “fullcheck”). In some examples, even if all frozen bit positions are permitted to be assigned PC bits, only those frozen bit positions having indices larger than smallest information bit index may be assigned PC bits. In some examples, the information set, PC set and frozen set may be defined for the total PC encoded vector. In some examples, the information set, PC set and frozen set may be additionally or alternatively defined for individual subblocks of the PC encoded vector.

The subchannel selection module 2016 determines, among the N polarized subchannels of polar codes, which K+J subchannels are for assigning PC encoded bits (which may include information bits), and which N−K−J subchannels are for frozen bits.

After PC encoding 2012, a length−(K+J) vector

$${v}_{0}^{K + J - 1}$$

is obtained, which may contain both information bits and PC bits, or PC bits only.

When the PC codes are a systematic code, the vector

$${v}_{0}^{K + J - 1}$$

contains both information bits and PC bits; for example, among the K+J bits, K bits are information bits and J bits are assistant bits.

When the PC codes are a non-systematic code, the vector

$${v}_{0}^{K + J - 1}$$

contains PC bits only; as a result, the input payload bits will not appear in

$${v}_{0}^{K + J - 1}$$

at all.

At a bit assignment step or stage 2014, the K+J bits are assigned to polarized subchannels. When necessary, zeros are inserted in between the K+J bits to generate a length-N vector for polar encoding. This may be represented as follows, where

$${v}_{0}^{N - 1}$$

denotes the zero-padded PC encoded vector.

$${v}_{0}^{K + J - 1} \to zero filling \to {v}_{0}^{N - 1}$$

The zero-filling is also governed by the subchannel selection module 2016, which inserts N−K−J bits with frozen bit value (typically zero, and could be masked by identifier bits).

Finally, the vector

$${v}_{0}^{N - 1}$$

(which may be zero-padded) is polar encoded at a polar encoding step or stage 2018 to obtain the polar codeword. The polar encoding 2018 may be represented by the following, where

$${c}_{0}^{N - 1}$$

denotes the polar codeword and G_{N} denotes the polar encoder matrix.

$${c}_{0}^{N - 1} = {v}_{0}^{N - 1} {G}_{N}$$

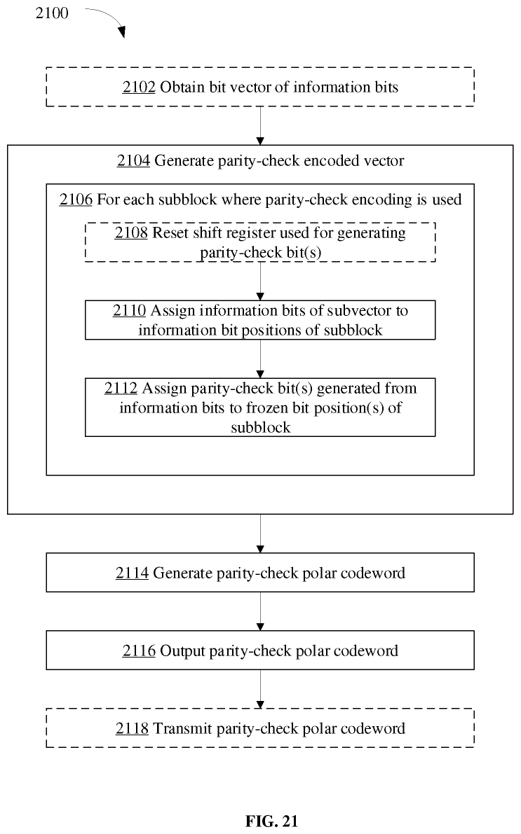

FIG. 21 is a flowchart illustrating an example method 2100 for generating a PC polar codeword. The method 2100 may be implemented by a processor executing instructions of the encoding module 2010 (and optionally the transmitting module 2020), for example. The method 2100 may be used to carry out various examples of PC-polar encoding described herein. In some examples, the method 2100 may be carried out by an apparatus that is acting as a transmitting device.

Optionally, at an operation 2102, a bit vector of information bits to be encoded may be obtained. For example, the bit vector of information bits may represent data (which may be generated by the apparatus or may be received by the apparatus) that is to be transmitted to an intended receiving device.

In some examples, the bit vector may comprise information bits associated with data transmissions having different redundancy versions. For example, the bit vector may comprise information bits corresponding to a first codeword (e.g., a first short polar codeword) for an initial data transmission (e.g., RV0) as well as information bits corresponding to a second codeword (e.g., a second short polar codeword) for a data retransmission (e.g., RV1).

At an operation 2104, a PC encoded vector is generated based on the bit vector of information bits to be encoded. The generated PC encoded vector may have a plurality of subblocks, and PC encoding may be independently applied or not applied to generate each subblock of the PC encoded vector. Whether or not PC encoding should be applied may be configured (e.g., based on a standard, or configured by a control signal). For example, a standard may define rules for applying PC encoding based on various factors (e.g., based on type of physical channel, one or more code parameters, one or more application scenarios, etc.), as described in the present disclosure.

As a detailed operation of the operation 2104, an operation 2106 may be performed for each subblock where PC encoding is used. The transmitting device may be configured to apply PC encoding to different subblocks according to certain rules, for example based on the length of each subblock, as described in the present disclosure. For simplicity, the following will refer to a first subblock of the PC encoded where PC encoding is used.

In some examples, PC encoding may be applied to a subvector of the input bit vector, where the subvector has a bit length that is a power of two. As described elsewhere in this disclosure, the bit vector may be divided into subvectors having a power-of-two length, and PC encoding may be applied to selected one or more of the power-of-two length subvectors.

Optionally, at an operation 2108, if a shift register is used to generate PC bit(s) for the first subblock, the shift register may be first reset or cleared. This may be useful where the same shift register is used to generate PC bit(s) for multiple subblocks. Resetting the shift register between subblocks may help to ensure that the PC bit(s) of one subblock is independent of another subblock (e.g., the PC bit(s) of a first subblock is not dependent on information bits of a second subblock, and PC bit(s) of a first subblock are decoupled from PC bit(s) of a second subblock). Clearing or resetting a shift register may mean resetting all elements of the shift register to have a value of zero or to have a predefined set of values, for example. In examples where the shift register is reset with a predefined set of values, the shift register may be reset to contain a set of values based on a radio network temporary identifier (RNTI), such as a UE-specific RNTI (e.g., RNTI of the intended receiving device), a common RNTI or a cell-specific RNTI, among other possibilities.

At an operation 2110, information bits of a first subvector of the bit vector are assigned to information bits positions of the first subblock. The information bits may be assigned to information bit positions of the first subblock based on an information set that defines the information bit positions of the first subblock.

At an operation 2112, one or more PC bits generated from the information bits of the first subvector are assigned to respective one or more frozen bit positions of the first subblock. The PC bit(s) may be assigned to frozen bit position(s) of the first subblock based on a frozen set that defines the frozen bit positions of the first subblock, or based on a PC set that defines the PC positions of the first subblock (and the PC set may be a subset of the frozen set). The PC bit(s) may be assigned to frozen bit position(s) at indices greater than the smallest information bit index. That is, frozen bit positions that come before the first information bit position may carry only frozen bit values, and PC bit(s) may be assigned to frozen bit positions having indices larger than the index of the first information bit in the first subblock. In some examples, all frozen bit positions may be allowed to carry PC bits. For example, all frozen bit positions having indices larger than the smallest information bit index may be assigned to carry a respective PC bit.

The PC bit(s) may be generated from the information bits using a cyclic shift operation, which may be implemented using a shift register (in particular a cyclic shift register), a hash function, a lookup table, software logic, or a pre-transformation matrix, for example. As previously described, if a shift register is used the shift register may be a cyclic shift register that is reset between subblocks. A pre-transformation matrix may be an upper triangular square matrix, where the matrix has dimensions matching the length of the subvector to which the pre-transformation matrix is applied. A lookup table may be suitable where each PC bit is generated based on a relatively small number of information bits (e.g., based on fewer than 20 information bits) and may be less suitable where the number of information bits used to generate a PC bit is longer, however a lookup table may still be used.

Notably, the PC bit(s) are generated from the information bits of the first subvector independently of any other subblock of the plurality of subblocks of the PC encoded vector. That is, the PC bit(s) assigned to the first subblock are not generated from the information bits of any other subblock (and similarly PC bit(s) assigned to another subblock are not generated from the information bits of the first subblock). This means that the PC bit(s) in the first subblock may be used to assist in decoding the information bits of the first subblock independently of any other subblock.

It may be noted that the bit positions of the first subblock may be filled bit-by-bit, for example by advancing the index of the first subblock one at a time and determining (e.g., based on the predefined frozen set, information set and PC set) whether the bit position at the current index should carry a frozen bit, an information bit or a PC bit. If the current bit position should carry a frozen bit, that bit position may be assigned a frozen bit value (e.g., a bit value of zero); if the current bit position should carry an information bit, that bit position may be assigned the next information bit in the subvector that has not yet been assigned; or if the current bit position should carry a PC bit, that bit position may be assigned the next PC bit (e.g., outputted from the cyclic shift operation, such as read out from a shift register, from a hash function or a lookup table, depending on implementation).

Thus, the operations 2110 and 2112 may be performed together to assign the appropriate bit to each bit position of the first subblock.

The operation 2106, including the optional operation 2108, the operation 2110 and the operation 2112, is performed for each subblock of the PC encoded vector where PC encoding is used.

For a second subblock of the PC encoded vector that does not require PC encoding, information bits of a second subvector of the bit vector are assigned to information bit positions of the second subblock (e.g., in accordance with the frozen set and information set defined for the second subblock) and there are no PC bits in the second subblock.

Thus, the PC encoded vector may include at least one subblock with PC encoding applied (i.e., has PC bits generated from information bits of that subblock). The PC encoded vector may or may not also include at least another subblock that has no PC encoding applied (i.e., no PC bits are generated from information bits of that subblock, and the subblock is free of PC bits). In some examples, a subblock that has PC encoding applied may correspond to a subvector that has a bit length that is a power of two, while a subblock that does not have PC encoding applied may correspond to a subvector that has a bit length that is other than a power of two.

After all subblocks have been generated for the PC encoded vector, the complete PC encoded vector may be provided as input to a polar encoder.

At an operation 2114, the PC polar codeword is generated by applying a polar code to the PC encoded vector. For example, a polar encoding matrix may be applied to the PC encoded vector.

At an operation 2116, the PC polar codeword is outputted. For example, the PC polar codeword may be outputted by the encoding module.

Optionally, at an operation 2118, the PC polar codeword may be transmitted. For example, a transmitting module of the transmitting device may transmit the PC polar codeword as a wireless communication signal over a communication channel to an intended receiving device.

As previously mentioned, there may be one or more rules or configurations for using PC encoding to generate a PC polar codeword depending on various factors, such as depending on the type of physical channel that the codeword is to be transmitted over, based on the type of traffic on the channel, based on one or more code parameters, based on one or more application scenarios, and combinations thereof. Some example configurations are now described, however these examples are not intended to be limiting.

An example configuration may be to use PC encoding based on the type of physical channel that the codeword is to be transmitted over and/or based on the type of uplink/downlink traffic in the channel. For example, PC encoding may be used to generate the codeword when the physical channel is a physical uplink control channel (PUCCH) that carries uplink control information (UCI) content including feedback (e.g., ACK or NACK feedback for HARQ retransmission schemes) and scheduling request (SR) information, and all other physical channels may not use PC encoding. In another example, PC encoding may be used to generate the codeword when the physical channel is a PUCCH that carries UCI content including channel state information (CSI), and all other physical channels may not use PC encoding. In another example, PC encoding may be used to generate the codeword when the physical channel is a PUCCH that is not multiplexed on a physical uplink shared channel (PUSCH), and all other physical channels may not use PC encoding. In another example, PC encoding may be used to generate the codeword when the physical channel is any PUCCH (including those multiplexed on PUSCH), and all other physical channels may not use PC encoding. In another example, PC encoding may be used to generate the codeword when the physical channel is a PUCCH or physical broadcast channel (PBCH), and all other physical channels may not use PC encoding. In another example, PC encoding may be used to generate the codeword when the physical channel is a PUCCH or a physical downlink control channel (PDCCH), and all other physical channels may not use PC encoding. In another example, PC encoding may be used to generate the codeword when the physical channel is a PUCCH, a PDCCH or a PBCH, and all other physical channels may not use PC encoding. In another example, PC encoding may be used to generate the codeword when the physical channel is a stage-1 PDCCH, and PC encoding may not be used when the physical channel is a stage-2 PDCCH. In another example, PC encoding may be used to generate the codeword when the physical channel is any control channel (e.g., PUCCH, PBCH or PDCCH), and PC encoding may not be used when the physical channel is a data channel (e.g., PUSCH, PDSCH). In another example, PC encoding may be used to generate the codeword when the physical channel is any uplink channel (e.g., PUCCH or PUSCH), and PC encoding may not be used when the physical channel is a downlink channel (e.g., PBCH, PDCCH or PDSCH). In some of the configurations described above, there may be a technical advantage in that performance may be enhanced for shorter polar codes. In some configurations, there may be also a technical advantage of a more unified design, enabling simpler description in standards.

Another example configuration may be to use PC encoding based on one or more code parameters. For example, PC encoding may be used to generate the codeword when a code length is within a maximum code length (which may be denoted N_{max,pc}) (e.g., the maximum code length may be a code length of 32, 64, 128, 256, 512 or 1024, among other possibilities). In another example, PC encoding may be used to generate the codeword when an information block length is within a maximum information block length (which may be denoted K_{max,pc}) (e.g., the maximum information block length may be a block length of 11, 16, 19, 22, 24, 32, 64, 128, 256 or 512, among other possibilities). In another example, PC encoding may be used to generate the codeword when the code rate is within a maximum code rate (denoted R_{max,pc}) (e.g., the maximum code rate may be a rate of ¾, ⅔, ½, ⅖, ⅜, ¼ or ⅛, among other possibilities). In another example, PC encoding may be used to generate the codeword when the code length is within a maximum code length N_{max,pc} (e.g., a maximum code length as described above) and is also within a maximum code rate R_{max,pc} (e.g., a maximum code rate as described above).

Another example configuration may be to use PC encoding based on a combination of physical channel type and one or more code parameters. For example, any combination of the configurations described above based on physical channel type and code parameters may be used. For example, PC encoding may be used to generate the codeword when the physical channel is PUCCH and the code length is within a maximum code length N_{max,pc} (e.g., the maximum code length may be a code length of 32, 64, 128, 256, 512 or 1024, among other possibilities). In another example, PC encoding may be used to generate the codeword when the physical channel is PUCCH and the information block length is within a maximum information block length K_{max,pc} (e.g., the maximum information block length may be a block length of 11, 16, 19, 22, 24, 32, 64, 128, 256 or 512, among other possibilities). In another example, PC encoding may be used to generate the codeword when the physical channel type is stage-2 PDCCH and the code length is within a maximum code length N_{max,pc} (e.g., the maximum code length may be a code length of 32, 64, 128, 256, 512 or 1024, among other possibilities). It should be understood that other combinations of the previously described configurations may be used.

Another example configuration may be to use PC encoding based on certain application scenarios and/or priority of the traffic (e.g., priority of the data represented by the information bits to be encoded). For example, PC encoding may be used to generate the codeword when the information bits are for ultra-reliable low-latency communication (URLLC) traffic, and PC encoding may not be used for other physical channels. In some examples, PC encoding may be used to generate the codeword when the information bits are for high-priority communications (e.g., traffic associated with certain priority index or indices indicating high priority), such as high priority UCI content or high priority data traffic.

Some example configurations may include one or more rules that specify how PC encoding should be performed to generate a PC polar codeword. Different techniques for PC encoding may be specified in combination with certain physical channel types and/or coding parameters. For example, a standard may include a table indicating a particular type of PC encoding for certain physical channels and certain coding parameters.

One type of PC polar encoding, which may be referred to as type I PC polar encoding (or type I PC-polar), may use a set or predefined number of PC bits per subblock, such as 3 PC bits, 6 PC bits or 8 PC bits. Another type of PC polar encoding, which may be referred to as type II PC polar encoding (or type II PC-polar), may allow all frozen bits in a subblock to be used as PC bits (it should be noted that, because PC bits are generated from information bits, typically only frozen bit positions at indices greater than the smallest information bit index may be used as PC bit positions).

For example, type-I PC-polar encoding may be used when the channel is PUCCH and the code length is within a maximum code length (e.g., within a maximum code length of 32, 64, 128, 256, 512 or 1024), and type-II PC-polar encoding may be used when the channel is PUCCH and the code length is greater than the maximum code length. In another example, type-I PC-polar encoding may be used when the channel is PUCCH and the information block length is within a maximum information block length (e.g., within a maximum information block length of 11, 16, 19, 22, 24, 32, 64, 128, 256 or 512), and type-II PC-polar encoding may be used when the channel is PUCCH and the information block length is greater than the maximum information block length. In another example, type-I PC-polar encoding may be used when the channel is PUCCH, and type-II PC-polar encoding may be used when the channel is PDCCH and/or PBCH.

As previously mentioned, there may be one or more rules or configurations for applying PC encoding to different subblocks, depending on various factors, such as depending on the length of the subvector used to generate a subblock. Some example configurations are now described, however these examples are not intended to be limiting.

An example configuration may be to divide a bit vector into subvectors of length power-of-two (in some examples, there may be a subvector that is not a power-of-two in length), and then PC encoding is applied to generate the first one or more subblocks (but fewer than all subblocks) from the subvectors. For example, PC encoding may be applied to generate the first one, first two or first four subblocks of the codeword. An advantage of this configuration is that more frozen bit positions may be assigned to carry PC bits, thus helping to achieve more coding gain. In another example configuration, a bit vector may be divided into subvectors of length power-of-two (in some examples, there may be a subvector that is not a power-of-two in length), and then PC encoding is applied to generate the first one or more subblocks containing information bits (but fewer than all subblocks) from corresponding subvectors. For example, PC encoding may be applied to generate the first one, first two or first four subblocks containing information bits in the codeword. This configuration may be useful because, in cases where PC bits can only be generated after there has been at least one information bit, only frozen bit positions having indices greater than the smallest information bit index can be used to carry PC bits. In another example configuration, a bit vector may be divided into subvectors of length power-of-two (in some examples, there may be a subvector that is not a power-of-two in length), and then PC encoding is applied to generate the last one or more subblocks (but fewer than all subblocks) from corresponding subvectors. For example, PC encoding may be applied to generate the last one, last two or last four subblocks of the codeword. An advantage of this configuration is that weight spectrum may be improved more when PC encoding is used in the last one or more subblocks. In another example configuration, a bit vector may be divided into subvectors of length power-of-two (in some examples, there may be a subvector that is not a power-of-two in length), and then PC encoding is applied to generate all the subblocks from corresponding subvectors. PC encoding may be applied independently or separately to generate each subblock. This means that the PC bits in a given subblock are generated from only the information bits of that given subblock. Thus, the PC bits in a given subblock may be used only to assist in decoding of that subblock (e.g., to check the information bits of that subblock). An advantage of this configuration is that subblock-wise SCL decoding may be used at the decoder of the receiving device, which may help to reduce memory usage.

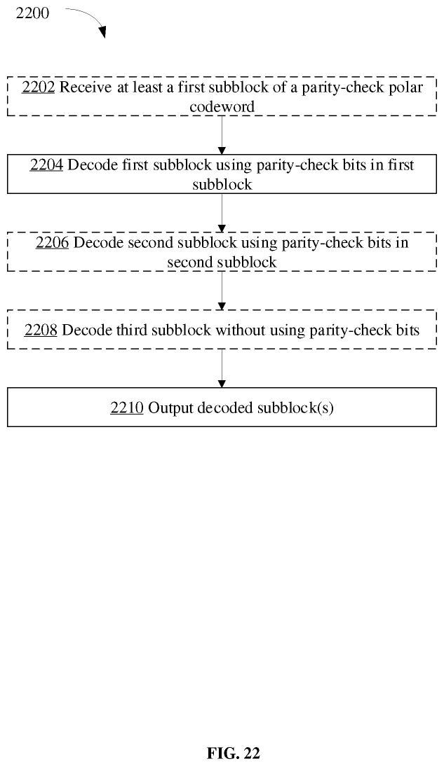

FIG. 22 is a flowchart illustrating an example method 2200 for decoding a PC polar codeword. The method 2200 may be implemented by a processor executing instructions of the decoding module 2030 (and optionally the receiving module 2040), for example. The method 2200 may be used to decode various examples of PC-polar codewords described herein. In some examples, the method 2200 may be carried out by an apparatus that is a receiving device.

Optionally, at an operation 2202, at least a first subblock of a PC polar codeword is received. For example, a receiving module may receive a wireless communication signal over a communication channel, where at least the first subblock of the PC polar codeword is carried by the signal. The PC polar codeword may comprise a plurality of subblocks. In some examples, not all subblocks of the PC polar codeword may be received. For example, only the first subblock may be received. In some examples, at least another second subblock and/or another third subblock of the PC polar codeword may be received. In some examples, all subblocks of the PC polar codeword may be received.

At an operation 2204, the first subblock is decoded using PC bits in the first subblock. The PC bits in the first subblock may be used to assist in decoding the first subblock independently of any other subblocks of the PC polar codeword. Thus, the first subblock may be decoded even if other subblocks of the PC polar codeword are not received. For example, even if only the first subblock is received, the first subblock may be successfully decoded using only the PC bits contained in the first subblock to assist in the decoding.

As previously discussed, a PC polar codeword may include one or more subblocks with PC encoding applied as well as one or more subblocks without PC encoding. Each type of subblock may be decoded independently.

Optionally, at an operation 2206, a second subblock that contains PC bits may be decoded using PC bits in the second subblock. The second subblock may be decoded using PC bits of the second subblock to assist in the decoding, independently of the first subblock.

Optionally, at an operation 2208, a third subblock that does not contain PC bits may be decoded without using PC bits. The third subblock may be decoded independently of the first and second subblocks.

At an operation 2210, the decoded subblock(s) are outputted.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

It should be understood that examples of the present disclosure may be embodied as a method, an apparatus, a non-transitory computer readable medium, a processing module, a chipset, a system chip or a computer program, among others. An apparatus may include a transmitting module configured to carry out transmitting steps described above and a receiving module configured to carry out receiving steps described above. An apparatus may include a processing module, processor or processing unit configured to control or cause the apparatus to carry out examples disclosed herein.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein. The machine-executable instructions may be in the form of code sequences, configuration information, or other data, which, when executed, cause a machine (e.g., a processor or other processing device) to perform steps in a method according to examples of the present disclosure.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

What is claimed is:

1. A method for generating a parity-check polar codeword, the method comprising:
generating a parity-check encoded vector based on a bit vector of information bits to be encoded, the parity-check encoded vector comprising a plurality of subblocks, wherein information bits of a first subvector of the bit vector are assigned to information bit positions of a first subblock of the plurality of subblocks, and one or more parity-check bits generated from the information bits of the first subvector are assigned to frozen bit positions of the first subblock;
generating the parity-check polar codeword by applying a polar code to the parity-check encoded vector; and
outputting the parity-check polar codeword.

2. The method of claim 1, wherein the one or more parity-check bits assigned to the frozen bit positions of the first subblock are generated independently of a second subblock of the plurality of subblocks.

3. The method of claim 2, wherein information bits of a second subvector of the bit vector are assigned to information bit positions of the second subblock, and wherein the second subblock is free of parity-check bits.

4. The method of claim 2, wherein:
the one or more parity-check bits generated from the information bits of the first subvector form a first set of the one or more parity-check bits;
information bits of a second subvector of the bit vector are assigned to information bit positions of the second subblock; and
a second set of the one or more parity-check bits generated from the information bits of the second subvector is assigned to frozen bit positions of the second subblock, the first set of the one or more parity-check bits being decoupled from the second set of the one or more parity-check bits.

5. The method of claim 4, wherein a cyclic shift register is used to generate the first set of the one or more parity-check bits and to generate the second set of the one or more parity-check bits, and wherein the cyclic shift register is cleared between generation of the first set of the one or more parity-check bits and generation of the second set of the one or more parity-check bits.

6. A method for decoding a parity-check polar codeword, the method comprising:
decoding at least a first subblock of the parity-check polar codeword having a plurality of subblocks by using one or more parity-check bits in the first subblock to assist in decoding the first subblock; and
outputting the decoded first subblock.

7. The method of claim 6, wherein the first subblock is received in absence of a second subblock of the plurality of subblocks.

8. The method of claim 6, wherein a second subblock of the plurality of subblocks is free of parity-check bits, the method further comprising:
decoding the second subblock independently of the first subblock; and
outputting the decoded second subblock.

9. The method of claim 6, further comprising:
decoding a second subblock of the plurality of subblocks by using another one or more parity-check bits in the second subblock to assist in decoding the second subblock, independently of the first subblock; and
outputting the decoded second subblock.

10. The method of claim 6, further comprising:
receiving at least the first subblock.

11. An apparatus for generating a parity-check polar codeword, comprising:
at least one processor coupled with at least one memory storing one or more instructions that, when executed by the at least one processor, cause the apparatus to perform operations comprising:
generating the parity-check encoded vector based on a bit vector of information bits to be encoded, the parity-check encoded vector comprising a plurality of subblocks, wherein information bits of a first subvector of the bit vector are assigned to information bit positions of a first subblock of the plurality of subblocks, and one or more parity-check bits generated from the information bits of the first subvector are assigned to frozen bit positions of the first subblock;
generating the parity-check polar codeword by applying a polar code to the parity-check encoded vector; and
outputting the parity-check polar codeword.

12. The apparatus of claim 11, wherein the one or more parity-check bits assigned to the frozen bit positions of the first subblock are generated independently of a second subblock of the plurality of subblocks.

13. The apparatus of claim 12, wherein information bits of a second subvector of the bit vector are assigned to information bit positions of the second subblock, and wherein the second subblock is free of parity-check bits.

14. The apparatus of claim 12, wherein:
the one or more parity-check bits generated from the information bits of the first subvector form a first set of the one or more parity-check bits;
information bits of a second subvector of the bit vector are assigned to information bit positions of the second subblock; and
a second set of the one or more parity-check bits generated from the information bits of the second subvector is assigned to frozen bit positions of the second subblock, the first set of the one or more parity-check bits being decoupled from the second set of the one or more parity-check bits.

15. The apparatus of claim 14, wherein a cyclic shift register is used to generate the first set of the one or more parity-check bits and to generate the second set of the one or more parity-check bits, and wherein the cyclic shift register is cleared between generation of the first set of the one or more parity-check bits and generation of the second set of the one or more parity-check bits.

16. An apparatus for decoding a parity-check polar codeword, comprising:
at least one processor coupled with at least one memory storing one or more instructions that, when executed by the at least one processor, cause the apparatus to perform operations comprising:
decoding at least a first subblock of the parity-check polar codeword having a plurality of subblocks by using one or more parity-check bits in the first subblock to assist in decoding the first subblock; and
outputting the decoded first subblock.

17. The apparatus of claim 16, wherein the first subblock is received in absence of a second subblock of the plurality of subblocks.

18. The apparatus of claim 16, wherein a second subblock of the plurality of subblocks is free of parity-check bits, and the operations further comprise:
decoding the second subblock independently of the first subblock; and
outputting the decoded second subblock.

19. The apparatus of claim 16, wherein the operations further comprise:
decoding a second subblock of the plurality of subblocks by using another one or more parity-check bits in the second subblock to assist in decoding the second subblock, independently of the first subblock; and
outputting the decoded second subblock.

20. The apparatus of claim 16, wherein the operations further comprise:
receiving at least the first subblock.
